(19) United States
(12) Patent Application Publication
(10) Pub. No.: US 2025/0212612 A1
(43) Pub. Date: Jun. 26, 2025

(54) DISPLAY DEVICE AND METHOD OF FABRICATING THE SAME

(71) Applicant: Samsung Display Co., LTD., Yongin-si (KR)

(72) Inventors: Che Ho LEE, Yongin-si (KR); Sae Bom AHN, Yongin-si (KR); So Yeon JEONG, Yongin-si (KR); Won Je JO, Yongin-si (KR); Jae Hyun KIM, Yongin-si (KR); Seok Hoon SEO, Yongin-si (KR)

(73) Assignee: Samsung Display Co., LTD., Yongin-si (KR)

(21) Appl. No.: 18/768,996

(22) Filed: Jul. 10, 2024

(30) Foreign Application Priority Data
Dec. 20, 2023 (KR) 10-2023-0186631

(51) Int. Cl. H10K 59/122; H10K 59/12

(52) U.S. Cl. CPC H10K 59/122; H10K 59/1201

(57) ABSTRACT

A display device includes an anode electrode on a light emission area of a substrate, a light emitting layer on the anode electrode, a first pixel defining layer on the non-light emission area of the substrate, including a first side directed toward the light emission area, a bank layer on the first pixel defining layer, including a tip more protruded toward the light emission area than the first side of the first pixel defining layer, a residual pattern that overlaps the non-light emission area and is disposed between the anode electrode and the first pixel defining layer, a cathode electrode on the light emitting layer and the bank layer, and an encapsulation layer on the cathode electrode. The first pixel defining layer and the bank layer are completely overlapped by the cathode electrode, and the entire first side of the first pixel defining layer physically contacts the cathode electrode.

### CROSS-REFERENCE TO RELATED APPLICATION(S)

This application claims priority to and benefits of Korean Patent Application No. 10-2023-0186631 under 35 U.S.C. § 119, filed on Dec. 20, 2023 in the Korean Intellectual Property Office, the entire contents of which are herein incorporated by reference.

### BACKGROUND

### 1. Technical Field

The disclosure relates to a display device and a method of fabricating the same.

### 2. Description of the Related Art

With the advancement of the information age, the demand for a display device for displaying an image has increased with various forms. For example, the display device has been applied to various electronic devices such as a smart phone, a digital camera, a laptop computer, a navigator and a smart television. The display device may be a flat panel display device such as a liquid crystal display device, a field emission display device, or an organic light emitting display device. Among the flat panel display devices, light emitting display devices include a light emitting element in which each of pixels of a display panel may self-emit light, thereby displaying an image even without a backlight unit that provides the display panel with light.

Recently, with the development of various electronic devices, there is an increasing demand for a display device of high resolution. In case of the display device of high resolution, since high pixel integration is involved, an interval between light emitting elements, which overlap each light emission area, may be narrowed. Therefore, the display device of high resolution may be formed by a pattern process of forming individual pixels rather than a mask process.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An aspect of the disclosure is to provide a display device in which a light emitting element is formed by a photo patterning process without a fine metal mask to provide high resolution and resolve a contact defect between a bank structure and a cathode electrode and a moisture permeation defect.

Aspects of the disclosure are not limited to those mentioned above and additional aspects of the disclosure, which are not mentioned herein, will be clearly understood by those skilled in the art from the following description of the disclosure.

According to an aspect of the disclosure, a display device may include a substrate including a light emission area and a non-light emission area, an anode electrode on the light emission area of the substrate, a light emitting layer on the anode electrode, a first pixel defining layer on the non-light emission area of the substrate, including a first side directed toward the light emission area, a bank layer on the first pixel defining layer, including a tip more protruded toward the light emission area than the first side of the first pixel defining layer, a residual pattern that overlaps the non-light emission area and is disposed between the anode electrode and the first pixel defining layer in a direction perpendicular to the substrate, a cathode electrode on the light emitting layer and the bank layer, and an encapsulation layer on the cathode electrode. The first pixel defining layer and the bank layer may be completely overlapped by the cathode electrode, and the entire first side of the first pixel defining layer may physically contact the cathode electrode.

In an embodiment, the first pixel defining layer may further include a second side facing the first side, and the entire second side may entirely physically contact the cathode electrode.

In an embodiment, the cathode electrode that may physically contact the first side and the cathode electrode that may physically contact the second side may be integral to each other.

In an embodiment, the bank layer may further include a tip more protruded than the second side.

In an embodiment, the tip of the bank layer may be more protruded than the first side, the tip of the bank layer, which may be more protruded than the first side, may overlap the light emission area, and the tip of the bank layer, which may be more protruded than the second side, may overlap the non-light emission area.

In an embodiment, the tip of the bank layer may be more protruded than the first side, and the tip of the first bank layer, which may be more protruded than the first side and the second side, may overlap the light emission area.

In an embodiment, a height of the first pixel defining layer may be greater than a height of the bank layer in a direction perpendicular to the substrate.

In an embodiment, the first pixel defining layer and the bank layer may include different materials.

In an embodiment, the first pixel defining layer may include at least one of silicon oxide and silicon oxynitride, and the bank layer may include at least one of titanium, silicon oxide, and silicon oxynitride.

In an embodiment, the display device may further include an organic pattern between the bank layer and the cathode electrode in a direction perpendicular to the substrate. The organic pattern and the light emitting layer may include a same material, the organic pattern may be spaced apart from the light emitting layer, and the cathode electrode may overlap the light emitting layer and the organic pattern.

In an embodiment, the bank layer may define a first opening, the first pixel defining layer may define a second opening, and the first opening may be disposed inside the second opening.

In an embodiment, the first opening may be completely surrounded by the second opening in a plan view.

In an embodiment, the display device may further include a second pixel defining layer spaced apart from the first pixel defining layer in a direction parallel with the substrate by overlapping the non-light emission area.

In an embodiment, the substrate may include a surface directed toward the anode electrode, and by overlapping the non-light emission area, the first surface may include a first portion physically contacting the first pixel defining layer, a second portion physically contacting the second pixel defining layer, and a third portion physically contacting the cathode electrode.

In an embodiment, the first portion and the second portion may be spaced apart from each other, and the third portion may be disposed between the first portion and the second portion.

In an embodiment, the display device may further include a capping layer disposed on the cathode electrode at a portion overlapping the light emission area, and a capping pattern on the first bank layer. The capping pattern and the capping layer may include a same material, and the capping layer and the capping pattern may be spaced apart from each other.

According to an aspect of the disclosure, a display device may include a substrate including a light emission area and a non-light emission area, an anode electrode on the light emission area of the substrate, a light emitting layer on the anode electrode, a pixel defining layer on the non-light emission area of the substrate, having a reverse tapered shape, an organic pattern on the first pixel defining layer, and spaced apart from the light emitting layer, a residual pattern that overlaps the non-light emission area and is disposed between the anode electrode and the pixel defining layer in a direction perpendicular to the substrate, and a cathode electrode on the light emitting layer and the organic pattern. The organic pattern and the light emitting layer may include a same material, the cathode electrode may completely overlap the pixel defining layer and the organic pattern, and both sides of the first pixel defining layer may entirely physically contact the cathode electrode.

In an embodiment, the display device may further include a second pixel defining layer spaced apart from the pixel defining layer in a direction parallel with the substrate by overlapping the non-light emission area, wherein the second pixel defining layer has a reverse tapered shape.

In an embodiment, the pixel defining layer and the second pixel defining layer may physically contact the residual pattern.

According to an aspect of the disclosure, a method of fabricating a display device may include forming a substrate including a light emission area and a non-light emission area, forming an anode electrode on the light emission area of the substrate, forming a sacrificial layer on the anode electrode, forming a pixel defining material layer entirely overlapping the substrate and the sacrificial layer, and forming a bank layer entirely overlapping the pixel defining layer. The method may further include forming photoresists on the bank layer and forming a first hole overlapped with the anode electrode and a second hole that is not overlapped with the anode electrode by performing a first etching process using the photoresists as masks, so that the anode electrode is exposed by overlapping the first hole, the sacrificial layer is formed as a residual pattern, and the bank layer forms a tip more protruded toward both sides than both sides of the pixel defining layer. The method may further include entirely forming a light emitting layer and a temporary barrier layer on the anode electrode and the bank layer and forming a photoresist on a portion overlapped with the anode electrode and a periphery of the anode electrode, and removing the light emitting layer and the temporary barrier layer at a portion where the photoresist is not formed, by performing a second etching process. The method may further include removing the temporary barrier layer disposed on the light emitting layer inside a vacuum chamber through a dry etching process, and entirely forming a cathode electrode and an encapsulation layer. Both sides of the pixel defining layer may entirely physically contact the cathode electrode.

Details of the other embodiments are included in the detailed description and drawings.

A display device according to an embodiment may include a pixel defining layer and a bank layer, which overlap a non-light emission area, so that a light emitting element overlapped with each light emission area may be formed without a fine metal mask. In addition, the display device according to an embodiment may include a temporary barrier layer covering light emitting layers, which are disposed to be spaced apart from each other, at a portion overlapped with each light emission area during a fabricating process of the display device, and a cathode electrode may be entirely grown in a subsequent process. Therefore, the display device according to an embodiment may resolve a contact defect of the cathode electrode and a moisture permeation defect of the display device, which are caused during the fabricating process.

Effects according to embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating an electronic device according to an embodiment;

FIG. 2 is a schematic perspective view illustrating a display device included in an electronic device according to an embodiment;

FIG. 3 is a schematic cross-sectional view illustrating a display device of FIG. 2;

FIG. 4 is a schematic plan view illustrating arrangement of a light emission area in a display area of FIG. 3;

FIG. 5 is a schematic cross-sectional view illustrating a display device taken along line X1-X1′ of FIG. 4;

FIG. 6 is an enlarged schematic cross-sectional view illustrating a first light emission area in FIG. 5;

FIG. 7 is an enlarged schematic cross-sectional view illustrating a non-light emission area disposed between a first light emission area and a second light emission area in FIG. 5;

FIG. 8 is a schematic cross-sectional view illustrating a display device taken along line X1-X1′ of FIG. 4 as another embodiment;

FIG. 9 is an enlarged schematic cross-sectional view illustrating a non-light emission area disposed between a first light emission area and a second light emission area in FIG. 8;

FIG. 10 is a schematic plan view illustrating arrangement of a light emission area in a display area of FIG. 3 as another embodiment;

FIG. 11 is a schematic cross-sectional view illustrating a display device taken along line X3-X3′ of FIG. 10; and

FIGS. 12 to 22 are schematic cross-sectional views illustrating a method of fabricating a display element layer and a thin film encapsulation layer, which are included in a display device of FIG. 5.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment. Like reference numerals and/or reference characters denote like elements.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there may be no intervening elements or layers present. The term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein may be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “has,” “have,” “having,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

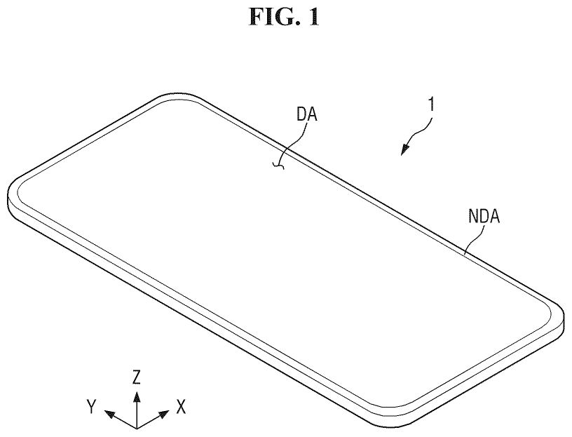

FIG. 1 is a schematic perspective view illustrating an electronic device 1 according to an embodiment.

Referring to FIG. 1, the electronic device 1 may display a moving image or a still image. The electronic device 1 may be an electronic device that provides a display screen. For example, a television, a laptop computer, a monitor, an advertising board, an Internet of Things device, a mobile phone, a smart phone, a tablet personal computer (PC), an electronic watch, smart glasses, a smart watch, a watch phone, a head mounted display, a mobile communication terminal, an electronic diary, an electronic book, a portable multimedia player (PMP), a navigator, a game machine, a digital camera, a camcorder and the like, which provide a display screen, may be the electronic device 1.

In FIG. 1, a first direction (X-axis direction), a second direction (Y-axis direction) and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. The first direction (X-axis direction) refers to a horizontal direction in the drawing, the second direction (Y-axis direction) refers to a vertical direction in the drawing, and the third direction (Z-axis direction) refers to an upper and lower direction in the drawing, that is, a thickness direction. In the following specification, unless otherwise specified, the “direction” may refer to both directions extended along the direction. In addition, in case that it is desirable to distinguish both “directions” extended to both sides, one side will be referred to as “a side direction” and the other side will be referred to as “another side direction”, respectively. Based on FIG. 1, a direction toward which an arrow indicating a direction is directed will be referred to as a side, and its opposite direction will be referred to as another side.

Hereinafter, for convenience of description, in case referring to the electronic device 1 or surfaces of each member constituting the electronic device 1, a direction in which an image is displayed, that is, a surface directed toward a side in the third direction (Z-axis direction) will be referred to as an upper surface, and its opposite surface will be referred to as another surface, but the disclosure is not limited thereto. The surface and another surface of the member may be referred to as a front surface and a rear surface, respectively, or may be referred to as a first surface or a second surface. In addition, in describing a relative position of each member of the electronic device 1, a side in the third direction (Z-axis direction) may be referred to as an upper portion, and another side in the third direction (Z-axis direction) may be referred to as a lower portion.

Various modifications may be made in a shape of the electronic device 1. For example, the electronic device 1 may have a shape such as a rectangle of a long width, a rectangle of a long length, a square, a rectangle of round corners (vertexes), other polygons or a circle.

The electronic device 1 may include a display area DA and a non-display area NDA. The display area DA is an area in which a screen may be displayed, and the non-display area NDA is an area in which a screen may not be displayed. The display area DA may be referred to as an active area, and the non-display area NDA may be referred to as a non-active area. The display area DA may generally occupy the center of the electronic device 1.

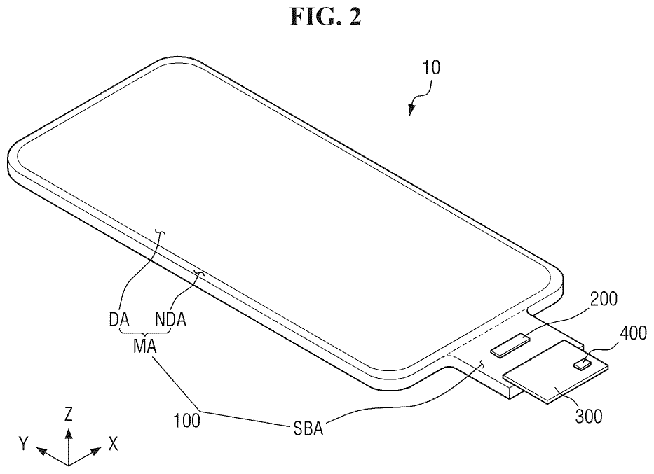

FIG. 2 is a schematic perspective view illustrating a display device 10 included in the electronic device 1 according to an embodiment.

Referring to FIG. 2, the electronic device 1 according to an embodiment may include a display device 10. The display device 10 may provide a screen displayed by the electronic device 1. Examples of the display device 10 may include an inorganic light emitting diode display device, an organic light emitting display device, a quantum dot light emitting display device, a plasma display device, and a field emission display device. The following description will be based on a case where the display device 10 is an organic light emitting diode display device, but the disclosure is not limited thereto, and the display device 10 may be another type of display device.

The display device 10 may have a planar shape similar to that of the electronic device 1. For example, the display panel 100 may have a planar shape similar to a rectangular shape having a short side in the first direction (X-axis direction) and a long side in the second direction (Y-axis direction). A corner at which the short side in the first direction (X-axis direction) meets the long side in the second direction (Y-axis direction) may be rounded to have a predetermined or selected curvature, but may be formed at a right angle without being limited thereto. The planar shape of the display device 10 may have another polygonal shape or a shape similar to a circular shape or an oval shape without being limited to the rectangular shape.

The display device 10 may include a display panel 100, a display driver 200, a circuit board 300, and a touch driver 400.

The display panel 100 may include a main area MA and a sub-area SBA. The main area MA may include a display area DA including pixels for displaying an image, and a non-display area NDA disposed near the display area DA.

The display area DA may emit light from light emission areas or openings. For example, the display panel 100 may include a pixel circuit including switching elements, a pixel defining layer defining a light emission area or an opening, and a self-light emitting element. For example, the self-light emitting element may include at least one of an organic light emitting diode, a quantum dot light emitting diode (LED) including a quantum dot light emitting layer, an inorganic light emitting diode (inorganic LED) including an inorganic semiconductor, and micro light emitting diode (micro LED), but is not limited thereto. In the following drawing, the self-light emitting element is an organic light emitting diode by way of example.

The non-display area NDA may be an outer area of the display area DA. The non-display area NDA may be defined as an edge area of the main area MA of the display panel 100.

The sub-area SBA may be an area extended from a side of the main area MA. The sub-area SBA may include a flexible material capable of being subjected to bending, folding, rolling and the like. For example, in case that the sub-area SBA is bent, the sub-area SBA may overlap the main area MA in the thickness direction (e.g., the third direction (Z-axis direction)). The sub-area SBA may include a pad portion connected to the display driver 200 and the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may be formed of an integrated circuit (IC), and may be packaged on the display panel 100 by a chip on glass (COG) method, a chip on plastic (COP) method or an ultrasonic bonding method. For example, the display driver 200 may be disposed in the sub-area SBA, and may overlap the main area MA in the thickness direction by bending of the sub-area SBA. As another example, the display driver 200 may be packaged on the circuit board 300.

The circuit board 300 may be attached onto the pad portion of the display panel 100 by using an anisotropic conductive film (ACF). The circuit board 300 may be a flexible printed circuit board, a printed circuit board, or a flexible film such as a chip on film.

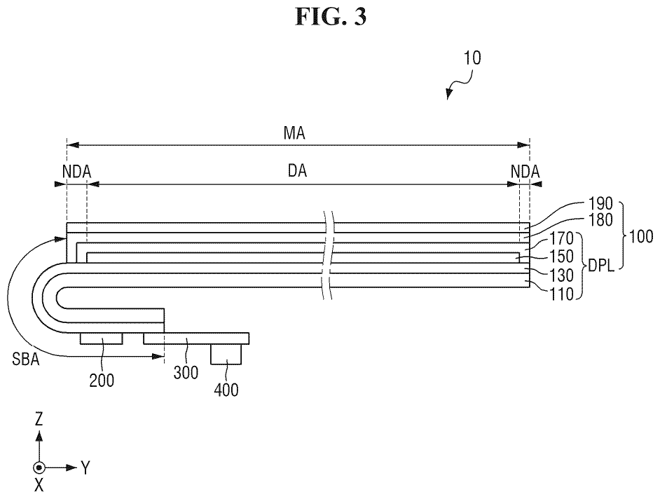

The touch driver 400 may be packaged on the circuit board 300. The touch driver 400 may be connected to a touch sensor layer (‘180’ of FIG. 3) of the display panel 100. The touch driver 400 may be formed of an integrated circuit (IC).

FIG. 3 is a schematic cross-sectional view illustrating the display device 10 of FIG. 2.

Referring to FIG. 3, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate capable of being subjected to bending, folding, rolling or the like. For example, the substrate 110 may include a polymer resin such as polyimide (PI), but is not limited thereto. In another embodiment, the substrate 110 may include a glass material or a metal material.

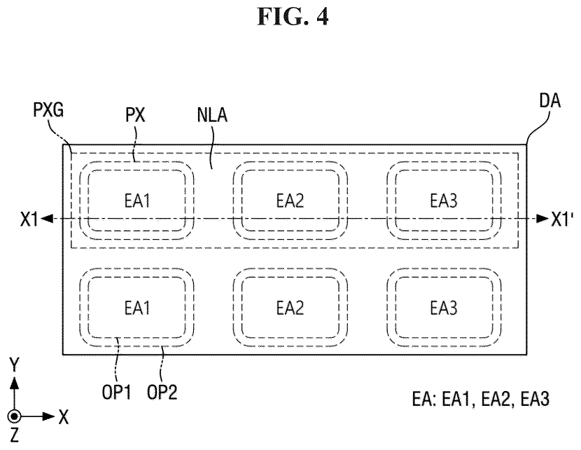

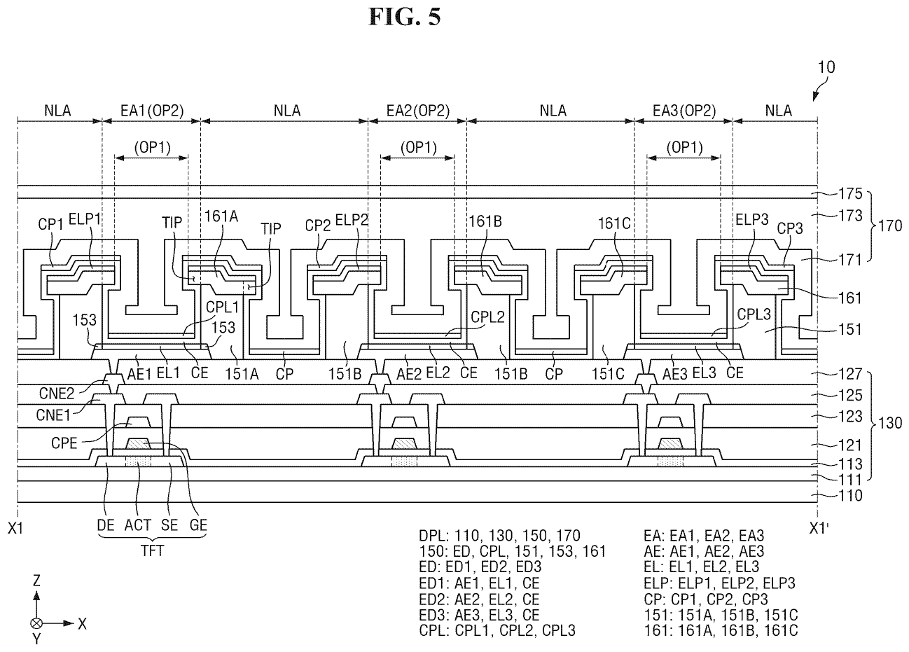

The thin film transistor layer 130 may be positioned (disposed) on the substrate 110. The thin film transistor layer 130 may be positioned in the display area DA, the non-display area NDA, and the sub-area SBA. The thin film transistor layer 130 may include thin film transistors (‘TFT’ of FIG. 5) constituting the pixels (‘PX’ of FIG. 4).

The display element layer 150 may be positioned on the thin film transistor layer 130. The display element layer 150 may be positioned to overlap the display area DA. The display element layer 150 may include light emitting elements (‘ED’ of FIG. 5). For example, the display element according to an embodiment may include at least one of an organic light emitting diode including an organic light emitting layer, a quantum dot light emitting diode (LED) including a quantum dot light emitting layer, an inorganic light emitting diode including an inorganic semiconductor, and a micro light emitting diode (Micro LED), but is not limited thereto.

The thin film encapsulation layer 170 may be positioned on the display element layer 150. The thin film encapsulation layer 170 may be positioned to overlap the display area DA and the non-display area NDA. The thin film encapsulation layer 170 may cover an upper surface and sides of the display element layer 150, and may protect the display element layer 150 from external oxygen and moisture. The thin film encapsulation layer 170 may include at least one inorganic layer and at least one organic layer for encapsulating the display element layer 150.

The touch sensor layer 180 may be positioned on the thin film encapsulation layer 170. The touch sensor layer 180 may be positioned to overlap the display area DA and the non-display area NDA. The touch sensor layer 180 may sense a user's touch in a mutual capacitance manner or a self-capacitance manner.

The color filter layer 190 may be positioned on the touch sensor layer 180. The color filter layer 190 may be positioned to overlap the display area DA and the non-display area NDA. The color filter layer 190 may reduce reflective light due to external light by absorbing a portion of light introduced from the outside of the display device 10. Therefore, the color filter layer 190 may prevent color distortion due to reflection of external light from occurring.

As the color filter layer 190 is directly disposed on the touch sensor layer 180, the display device 10 may not require a separate substrate for the color filter layer 190. Therefore, a thickness of the display device 10 may be relatively small. In addition, the color filter layer 190 may be omitted depending on the embodiment.

As shown in FIG. 3, a portion of the display layer DPL overlapped with the sub-area SBA may be bent. In case that a portion of the display layer DPL is bent, the display driver 200, the circuit board 300 and the touch driver 400 may overlap the main area MA in the third direction (Z-axis direction).

FIG. 4 is a schematic plan view illustrating arrangement of the light emission area EA in the display area DA of FIG. 3.

Referring to FIG. 4, the display area DA according to an embodiment may include multiple first to third light emission areas EA1, EA2 and EA3 and a non-light emission area NLA. The non-light emission area NLA may be positioned to surround the first to third light emission areas EA1, EA2 and EA3.

The non-light emission area NLA may shield light emitted from each of the first to third light emission areas EA1, EA2 and EA3. For this reason, the non-light emission area NLA may assist so that light emitted from the first to third light emission areas EA1, EA2 and EA3 may not be mixed. A pixel defining layer (‘151’ of FIG. 5) and a bank layer (‘161’ of FIG. 5), which will be described later, may be disposed in the non-light emission area NLA.

The light emission area EA may include a first light emission area EA1, a second light emission area EA2 and a third light emission area EA3, which emit light of different colors. Each of the first to third light emission areas EA1, EA2 and EA3 may emit red, green or blue light, and the color of light emitted from each of the first to third light emission areas EA1, EA2 and EA3 may be different depending on a type of a light emitting element ED that will be described later. For example, the first light emission area EA1 may emit red light of a first color, the second light emission area EA2 may emit green light of a second color and the third light emission area EA3 may emit blue light of a third color, but the disclosure is not limited thereto. Although the first to third light emission areas EA1, EA2 and EA3 are shown as having the same size and shape, the disclosure is not limited thereto. The size and shape of each of the first to third light emission areas EA1, EA2 and EA3 may be freely adjusted depending on desired characteristics.

The first to third light emission areas EA1, EA2 and EA3 may be defined by a first opening OP1 and a second opening OP2. For example, the first opening OP1 may be defined by a bank layer 161 that will be described later, and the second opening OP2 may be defined by the pixel defining layer 151 that will be described later.

In some embodiments, at least one first light emission area EA1, at least one second light emission area EA2 and at least one third light emission area EA3, which are disposed to be adjacent to one another, may constitute one pixel group PXG. The pixel group PXG may be a minimum unit for emitting white light. However, various modifications may be made in the type and/or number of the first to third light emission areas EA1, EA2 and EA3 constituting the pixel group PXG depending on the embodiments.

FIG. 5 is a schematic cross-sectional view illustrating a display device 10 taken along line X1-X1′ of FIG. 4. FIG. 5 illustrates a schematic cross-section of a display layer DPL of the display device 10 according to an embodiment. Since the substrate 110 has already been described in FIG. 3, its redundant description will be omitted.

Referring to FIG. 5, the thin film transistor layer 130 may be positioned on the substrate 110. The thin film transistor layer 130 may include a first buffer layer 111, a thin film transistor TFT, a gate insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be positioned on the substrate 110. The first buffer layer 111 may include an inorganic layer capable of preventing permeation of the air or moisture. For example, the first buffer layer 111 may include multiple inorganic layers that are stacked on each other.

The thin film transistor TFT may be disposed on the first buffer layer 111, and may constitute a pixel circuit connected to each of the pixels. For example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be disposed on the first buffer layer 111. The active layer ACT may overlap the gate electrode GE in the third direction (Z-axis direction), and may be insulated from the gate electrode GE by the gate insulating layer 113. A portion of the active layer ACT may be conductorized to form the source electrode SE and the drain electrode DE.

The gate electrode GE may be positioned on the gate insulating layer 113. The gate electrode GE may overlap the active layer ACT with the gate insulating layer 113 interposed therebetween.

The gate insulating layer 113 may be positioned on the active layer ACT. The gate insulating layer 113 may cover the active layer ACT and the first buffer layer 111, and may insulate the active layer ACT from the gate electrode GE. The gate insulating layer 113 may include a contact hole through which the first connection electrode CNE1 passes.

The first interlayer insulating layer 121 may cover the gate electrode GE and the gate insulating layer 113. The first interlayer insulating layer 121 may include a contact hole through which the first connection electrode CNE1 passes. The contact hole of the first interlayer insulating layer 121 may be connected to a contact hole of the gate insulating layer 113 and a contact hole of the second interlayer insulating layer 123.

The capacitor electrode CPE may be positioned on the first interlayer insulating layer 121. The capacitor electrode CPE may overlap the gate electrode GE in the third direction (Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may include a contact hole through which the first connection electrode CNE1 passes. The contact hole of the second interlayer insulating layer 123 may be connected to the contact hole of the first interlayer insulating layer 121 and the contact hole of the gate insulating layer 113.

The first connection electrode CNE1 may be disposed on the second interlayer insulating layer 123. The first connection electrode CNE1 may electrically connect the drain electrode DE of the thin film transistor TFT to the second connection electrode CNE2. The first connection electrode CNE1 may be inserted into the contact holes formed in the first interlayer insulating layer 121, the second interlayer insulating layer 123 and the gate insulating layer 113, and thus may be in contact with the drain electrode DE of the thin film transistor TFT.

The first via layer 125 may cover the first connection electrode CNE1 and the second interlayer insulating layer 123. The first via layer 125 may planarize a lower structure. The first via layer 125 may include a contact hole through which the second connection electrode CNE2 passes.

The second connection electrode CNE2 may be positioned on the first via layer 125. The second connection electrode CNE2 may be inserted into the contact hole formed in the first via layer 125 to contact the first connection electrode CNE1. The second connection electrode CNE2 may electrically connect the first connection electrode CNE1 to first to third anode electrodes AE1, AE2 and AE3.

The second via layer 127 may cover the second connection electrode CNE2 and the first via layer 125. The second via layer 127 may include a contact hole through which the first to third anode electrodes AE1, AE2 and AE3 pass.

The display element layer 150 may be positioned on the second via layer 127. The display element layer 150 may include a light emitting element ED, a pixel defining layer 151, a residual pattern 153, a capping layer CPL and a bank layer 161.

The light emitting element ED of an embodiment may include a first light emitting element ED1 disposed in a portion overlapped with the first light emission area EA1, a second light emitting element ED2 disposed in a portion overlapped with the second light emission area EA2, and a third light emitting element ED3 disposed in a portion overlapped with the third light emission area EA3. The first light emitting element ED1 may include a first anode electrode AE1, a first light emitting layer EL1 and a cathode electrode CE, the second light emitting element ED2 may include a second anode electrode AE2, a second light emitting layer EL2 and a cathode electrode CE, and the third light emitting element ED3 may include a third anode electrode AE3, a third light emitting layer EL3 and a cathode electrode CE. The light emitting elements ED1, ED2 and ED3 may emit light of different colors depending on the material of the first to third light emitting layers EL1, EL2 and EL3. For example, the first light emitting element ED1 may emit red light of a first color, the second light emitting element ED2 may emit green light of a second color, and the third light emitting element ED3 may emit blue light of a third color.

The anode electrode AE of an embodiment may be positioned on the second via layer 127. The anode electrode AE may be electrically connected to the drain electrode DE of the thin film transistor TFT through the first connection electrode CNE1 and the second connection electrode CNE2.

The anode electrode AE of an embodiment may include a first anode electrode AE1 disposed in the first light emission area EA1, a second anode electrode AE2 disposed in the second light emission area EA2, and a third anode electrode AE3 disposed in the third light emission area EA3. The first anode electrode AE1, the second anode electrode AE2 and the third anode electrode AE3 may be disposed to be spaced apart from one another on the second via layer 127.

The anode electrode AE of an embodiment may have a stacked layer structure in which a material layer, which has a high work function, such as indium tin oxide (ITO), indium zinc oxide (IZO), zinc oxide (ZnO) and indium oxide (In₂O₃), and a reflective material layer such as Ag, Mg, Al, Pt, Pb, Pd, Au, Ni, Nd, Ir, Cr, Li, Ca or their mixture are stacked. For example, the first to third anode electrodes AE1, AE2 and AE3 may have a multi-layered structure of ITO/Mg, ITO/MgF, ITO/Ag, and ITO/Ag/ITO, but is not limited thereto.

The pixel defining layer 151 of an embodiment may be positioned at a portion overlapped with the non-light emission area NLA, and may be positioned on the second via layer 127 and the anode electrode AE. The pixel defining layer 151 of an embodiment may define the second opening OP2, and may expose the anode electrode AE at a portion overlapped with the second opening OP2.

The pixel defining layer 151 of an embodiment may separate and insulate the first to third anode electrodes AE1, AE2 and AE3 from one another at the portions overlapped with the first to third light emission areas EA1, EA2 and EA3. The pixel defining layer 151 of an embodiment may assist so that the first to third light emitting elements ED1, ED2 and ED3 spaced apart from one another may be formed at the portions overlapped with the first to third light emission areas EA1, EA2 and EA3 during the fabricating process of the display device 10.

In some embodiments, the pixel defining layer 151 may include a first pixel defining layer 151A, a second pixel defining layer 151B, and a third pixel defining layer 151C. The first pixel defining layer 151A of an embodiment may be disposed toward the first light emission area EA1, the second pixel defining layer 151B may be disposed toward the second light emission area EA2, and the third pixel defining layer 151C may be positioned toward the third light emission area EA3. The first pixel defining layer 151A and the second pixel defining layer 151B may be spaced apart from each other in the first direction (X-axis direction) at a portion overlapped with the non-light emission area NLA. The second pixel defining layer 151B and the third pixel defining layer 151C may be spaced apart from each other in the first direction (X-axis direction) at a portion overlapped with the non-light emission area NLA. The first pixel defining layer 151A, the second pixel defining layer 151B and the third pixel defining layer 151C may be integrally formed during the fabricating process of the display device 10, and then may be formed to be spaced apart from one another by a subsequent etching process. The fabricating process will be described later.

The bank layer 161 of an embodiment may be positioned at a portion overlapped with the non-light emission area NLA, and may be positioned on the pixel defining layer 151. The bank layer 161 of an embodiment may define the first opening OP1.

The bank layer 161 of an embodiment may include a tip TIP protruded to both sides toward the first to third light emission areas EA1, EA2 and EA3 and the non-light emission area NLA. In the display device 10 according to an embodiment, as the bank layer 161 includes the tip TIP, the first to third light emitting layers EL1, EL2 and EL3 disposed to be spaced apart from one another at portions overlapped with the first to third light emission areas EA1, EA2 and EA3 may be formed even without a separate fine metal mask during the fabricating process of the display device 10.

In some embodiments, the bank layer 161 of an embodiment may include a first bank layer 161A, a second bank layer 161B and a third bank layer 161C. The first bank layer 161A of an embodiment may be disposed on the first pixel defining layer 151A, the second bank layer 161B may be disposed on the second pixel defining layer 151B, and the third bank layer 161C may be positioned on the third pixel defining layer 151C. The first bank layer 161A and the second bank layer 161B may be spaced apart from each other in the first direction (X-axis direction) at a portion overlapped with the non-light emission area NLA. The second bank layer 161B and the third bank layer 161C may be spaced apart from each other in the first direction (X-axis direction) at a portion overlapped with the non-light emission area NLA. The first bank layer 161A, the second bank layer 161B and the third bank layer 161C may be integrally formed during the fabricating process of the display device 10, and then may be formed to be spaced apart from one another by a subsequent etching process. The fabricating process will be described later.

The light emitting layer EL of an embodiment may be disposed on the anode electrode AE. The light emitting layer EL may be an organic light emitting layer made of an organic material. In case that the thin film transistor TFT applies a predetermined or selected voltage to the anode electrode AE and the cathode electrode CE receives a common voltage, holes and electrons may move to the light emitting layer EL through a hole transport layer and an electron transport layer, respectively, and may be combined with each other in the light emitting layer EL to emit light.

The light emitting layer EL of an embodiment may include a first light emitting layer EL1, a second light emitting layer EL2 and a third light emitting layer EL3, which are respectively disposed in the first to third light emission areas EA1, EA2 and EA3. As described above, the first to third light emitting layers EL1, EL2 and EL3 of an embodiment may be positioned to be spaced apart from the first to third light emission areas EA1, EA2 and EA3 by the pixel defining layer 151 and the bank layer 161. For example, the first light emitting layer EL1 may be a light emitting layer for emitting red light of a first color, the second light emitting layer EL2 may be a light emitting layer for emitting green light of a second color, and the third light emitting layer EL3 may be a light emitting layer for emitting blue light of a third color, but the disclosure is not limited thereto.

The residual pattern 153 will be described later.

The organic pattern ELP of an embodiment may be positioned on the bank layer 161. The organic pattern ELP of an embodiment may be positioned to surround the periphery of the first opening OP1. The organic pattern ELP of an embodiment may be positioned at a portion overlapped with the light emission area EA and the non-light emission area NLA.

The organic pattern ELP of an embodiment may include a first organic pattern ELP1, a second organic pattern ELP2, and a third organic pattern ELP3. The first organic pattern ELP1 may be positioned on the first bank layer 161A, the second organic pattern ELP2 may be positioned on the second bank layer 161B, and the third organic pattern ELP3 may be positioned on the third bank layer 161C.

The first to third organic patterns ELP1, ELP2 and ELP3 may include the same material as that of each of the first to third light emitting layers EL1, EL2 and EL3. As described above, the light emitting layer EL of an embodiment may be formed by deposition and photo patterning processes without using a separate fine metal mask during the fabricating process of the display device 10. Therefore, the material for forming the light emitting layer EL may be not only deposited on the anode electrode AE but also deposited on the bank layer 161. That is, the organic pattern ELP of an embodiment may be a mark of the material of the light emitting layer EL deposited on the bank layer 161, which is formed by being disconnected from the light emitting layer EL deposited on the anode electrode AE, as the bank layer 161 of an embodiment includes the tip TIP. In other words, it can be seen that the display device 10 of an embodiment includes the organic pattern ELP on the bank layer 161, and thus the process of forming the light emitting layer EL is performed by the photo patterning process. However, the organic pattern ELP may be omitted depending on the process.

The cathode electrode CE of an embodiment may be entirely formed by overlapping the light emission area EA and the non-light emission area NLA. The cathode electrode CE of an embodiment may be in contact with the first to third light emitting layers EL1, EL2 and EL3 at portions overlapped with the first to third light emission areas EA1, EA2 and EA3, and may be in contact with the first to third organic patterns ELP1, ELP2 and ELP3 and the second via layer 127 at a portion overlapped with the non-light emission area NLA. The cathode electrode CE of an embodiment may be a common electrode.

The cathode electrode CE of an embodiment may include a transparent conductive material. For example, the cathode electrode CE may include a material layer having a small work function, such as Li, Ca, LiF/Ca, LiF/Al, Al, Mg, Ag, Pt, Pd, Ni, Au Nd, Ir, Cr, BaF, Ba or their compound or mixture (e.g., a mixture of Ag and Mg). The cathode electrode CE may further include a transparent metal oxide layer disposed on the material layer having a small work function.

The capping layer CPL of an embodiment may be positioned on the cathode electrode CE. The capping layer CPL may include an inorganic insulating material to prevent the light emitting elements ED from being damaged from the external air. In addition, the capping layer CPL may prevent the light emitting elements ED from being lifted off during the fabricating process of the display device 10.

The capping layer CPL may include a first capping layer CPL1 disposed on a portion overlapped with the first light emission area EA1, a second capping layer CPL2 disposed on a portion overlapped with the second light emission area EA2, and a third capping layer CPL3 disposed on a portion overlapped with the third light emission area EA3. The first to third capping layers CPL1, CPL2 and CPL3 may be spaced apart from one another with the pixel defining layer 151 interposed therebetween.

The capping layer CPL of an embodiment may include an inorganic insulating material. For example, the capping layer CPL may include aluminum oxide, titanium oxide, tantalum oxide, hafnium oxide, zinc oxide, silicon oxide, silicon nitride, and silicon oxynitride.

The capping pattern CP of an embodiment may be positioned at a portion overlapped with the bank layer 161, and may be in contact with the cathode electrode CE. The capping pattern CP of an embodiment may be positioned at portions overlapped with the light emission area EA and the non-light emission area NLA.

The capping pattern CP of an embodiment may include a first capping pattern CP1, a second capping pattern CP2, and a third capping pattern CP3. The first capping pattern CP1 may be positioned on the first bank layer 161A, the second capping pattern CP2 may be positioned on the second bank layer 161B, and the third capping pattern CP3 may be positioned on the third bank layer 161C.

The first to third capping patterns CP1, CP2 and CP3 may include the same material as that of the first to third capping layers CPL1, CPL2 and CPL3. The capping layer CPL may be formed by deposition and photo patterning processes without using a separate fine metal mask during the fabricating process of the display device 10. Therefore, the material for forming the capping layer CPL may be not only deposited on the anode electrode AE but also deposited on the bank layer 161 during the fabricating process of the display device 10. That is, the capping pattern CP of an embodiment may be a mark of the material of the capping layer CPL deposited on the bank layer 161, which is formed by being disconnected from the capping layer CPL deposited on the anode electrode AE, as the bank layer 161 includes the tip TIP. In other words, it can be seen that the display device 10 of an embodiment includes the capping pattern CP on the bank layer 161, and thus the process of forming the capping layer CPL is performed by the photo patterning process. However, the capping pattern CP may be omitted depending on the process.

In addition, the capping pattern CP of an embodiment may be deposited on the cathode electrode CE at a portion overlapped between the first pixel defining layer 151A and the second pixel defining layer 151B and between the second pixel defining layer 151B and the third pixel defining layer 151C at a portion overlapped with the non-light emission area NLA. The first to third capping patterns CP1, CP2 and CP3 formed on the bank layer 161 and the capping pattern CP formed between the pixel defining layers 151 may be spaced apart from each other.

The thin film encapsulation layer 170 of an embodiment may be positioned on the display element layer 150. The thin film encapsulation layer 170 may include at least one inorganic layer to prevent oxygen or moisture from being permeated into the display element layer 150. The thin film encapsulation layer 170 may include at least one organic layer to protect the display element layer 150 from particles such as dust. The thin film encapsulation layer 170 may include a first encapsulation layer 171, a second encapsulation layer 173, and a third encapsulation layer 175, which are stacked on each other.

The first encapsulation layer 171 of an embodiment may be positioned on the capping layer CPL and the capping pattern CP. Since the first encapsulation layer 171 of an embodiment may be formed through a chemical vapor deposition (CVD) process, it may be formed to have a uniform thickness along a profile of the lower structure. That is, the first encapsulation layer 171 of an embodiment may include a step difference at portions overlapped with the light emission area EA and the non-light emission area NLA.

The first encapsulation layer 171 of an embodiment may include a single layered structure or a multi-layered structure, and may include an inorganic insulating material. For example, the first encapsulation layer 171 may include at least one of aluminum oxide, titanium oxide, tantalum oxide, hafnium oxide, zinc oxide, silicon oxide, silicon nitride, and silicon oxynitride.

The second encapsulation layer 173 of an embodiment may be positioned on the first encapsulation layer 171. The second encapsulation layer 173 may planarize a step difference formed by the first encapsulation layer 171 at portions overlapped with the light emission area EA and the non-light emission area NLA.

The second encapsulation layer 173 may include a polymer-based material. For example, the second encapsulation layer 173 may include an acrylic resin, a silicon-based resin, a silicon acrylic resin, an epoxy-based resin, etc. The second encapsulation layer 173 may be formed by curing a monomer or coating a polymer.

The third encapsulation layer 175 of an embodiment may be positioned on the second encapsulation layer 173, and may completely cover the second encapsulation layer 173. The third encapsulation layer 175 may include an inorganic material, and may include the same material as that of the first encapsulation layer 171. A redundant description will be omitted.

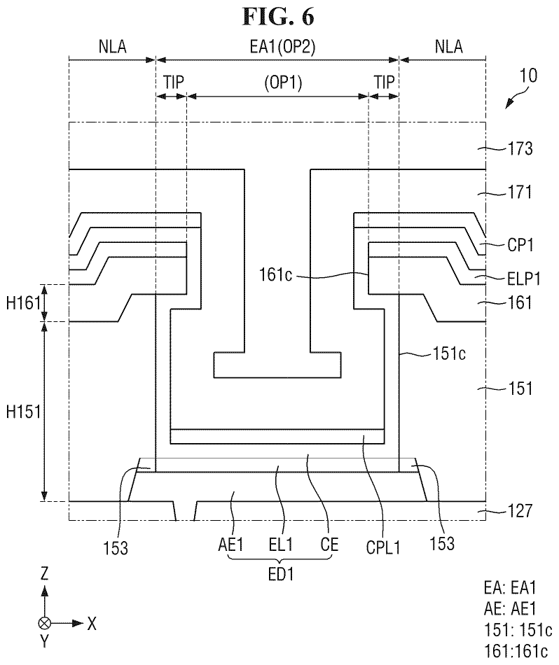

FIG. 6 is an enlarged schematic cross-sectional view illustrating the first light emission area EA1 in FIG. 5. Although the first pixel defining layer 151A of the pixel defining layer 151 and the first bank layer 161A of the bank layer 161 are shown in FIG. 6, for convenience of description, hereinafter, the pixel defining layer 151 and the bank layer 161 will be described.

Referring to FIG. 6, the residual pattern 153 of an embodiment may be positioned between the pixel defining layer 151 and the first anode electrode AE1 in the third direction (Z-axis direction). The residual pattern 153 of an embodiment may be positioned in contact with both sides of the first light emitting layer EL1 in the first direction (X-axis direction).

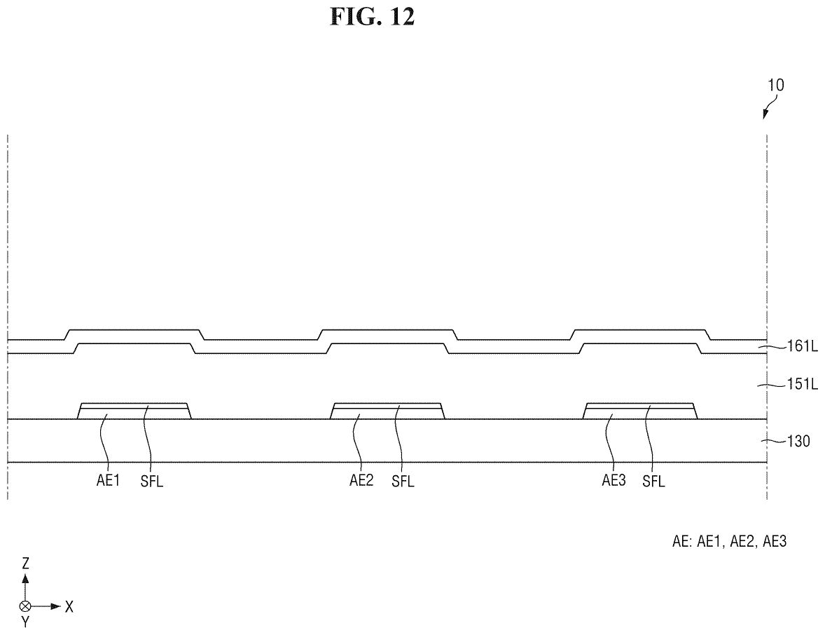

The display device 10 according to an embodiment may include a sacrificial layer (‘SFL’ of FIG. 12) on the anode electrode AE during the fabricating process. The sacrificial layer SFL may be disposed between the pixel defining layer 151 and the anode electrode AE, and then may be partially removed by a subsequent etching process. In this case, the sacrificial layer SFL, which is not partially removed, may remain as the residual pattern 153 between the pixel defining layer 151 and the anode electrode AE. The fabricating process will be described later.

The residual pattern 153 of an embodiment may include an oxide semiconductor. For example, the residual pattern 153 may include at least one of indium gallium zinc oxide (IGZO), zinc tin oxide (ZTO), and indium tin oxide (IZO).

The pixel defining layer 151 of an embodiment may be positioned in contact with the second via layer 127 and the first anode electrode AE1. In addition, the pixel defining layer 151 may be in contact with the residual pattern 153. The pixel defining layer 151 of an embodiment may include an inorganic insulating material. For example, the pixel defining layer 151 may include any one of silicon oxide and silicon oxynitride.

In some embodiments, the pixel defining layer 151 of an embodiment may include a first side 151c directed toward the first opening OP1. The first side 151c of an embodiment may be completely covered by the cathode electrode CE, and the first side 151c may be entirely in contact with the cathode electrode CE.

In the display device 10 of an embodiment, the first side 151c of the pixel defining layer 151 and the cathode electrode CE are formed to be entirely in contact with each other, so that a contact force between the pixel defining layer 151 and the cathode electrode CE may be improved. Therefore, the display device 10 of an embodiment may resolve a detachable defect of the pixel defining layer 151 and the cathode electrode CE and a moisture permeation defect caused by the detachable defect.

The bank layer 161 of an embodiment may be positioned in contact with the pixel defining layer 151. The bank layer 161 of an embodiment may include a material that is more stable for an etching process than the pixel defining layer 151. For example, the bank layer 161 may include a conductive metal material or an inorganic insulating material.

For example, in case that the bank layer 161 of an embodiment includes a conductive metal material, the bank layer 161 may include one or more metals selected from titanium (Ti), molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), tantalum (Ta), tungsten (W), and copper (Cu).

For example, in case that the bank layer 161 of an embodiment includes an inorganic insulating material, the bank layer 161 may include at least one of silicon oxide and silicon oxynitride. In case that the bank layer 161 includes an inorganic insulating material, the bank layer 161 and the pixel defining layer 151 may include their respective materials different from each other. For example, in case that the pixel defining layer 151 includes silicon oxynitride, the bank layer 161 may be formed of silicon oxide.

In some embodiments, the bank layer 161 of an embodiment may include a first side 161c directed toward the first opening OP1. The first side 161c of the bank layer 161 may be protruded toward the first light emission area EA1 in the first direction (X-axis direction). In other words, the first side 151c of the pixel defining layer 151 according to an embodiment may have a shape more recessed in the first direction (X-axis direction) than the first side 161c of the bank layer 161.

The pixel defining layer 151 and the bank layer 161 according to an embodiment may be formed through the same etching process during the fabricating process of the display device 10. Since the bank layer 161 of an embodiment includes a material that is more stable for an etching process than the pixel defining layer 151, the bank layer 161 may have an etching ratio lower than that of the pixel defining layer 151 in the same etching process. Therefore, the bank layer 161 of an embodiment may have a tip TIP more protruded toward the light emission area EA than the first side 151c of the pixel defining layer 151, and an undercut may be formed between the first side 151c of the pixel defining layer 151 and the protruded tip TIP of the bank layer 161.

A height H151 of the pixel defining layer 151 according to an embodiment may be greater than a height H161 of the bank layer 161.

The first organic pattern ELP1 of an embodiment may be positioned in contact with the bank layer 161. The first organic pattern ELP1 may overlap the tip TIP of the bank layer 161 and the residual pattern 153 in the third direction (Z-axis direction). Other redundant description will be omitted.

The cathode electrode CE of an embodiment may be positioned in contact with the first light emitting layer EL1 at a portion overlapped with the first opening OP1, and may completely cover the first light emitting layer EL1. The cathode electrode CE of an embodiment may completely cover the first side 151c of the pixel defining layer 151, the tip TIP of the bank layer 161 and the first organic pattern ELP1 at a portion overlapped with the second opening OP2, and may be in contact with the pixel defining layer 151, the bank layer 161 and the first organic pattern ELP1. In addition, the cathode electrode CE may completely cover the first organic pattern ELP1 at a portion overlapped with the non-light emission area NLA, and may be in contact with the first organic pattern ELP1.

The first capping layer CPL1 of an embodiment may be positioned on the first light emitting element ED1 at a portion overlapped with the first opening OP1, and may be positioned in contact with the cathode electrode CE. The first capping pattern CP1 of an embodiment may overlap the tip TIP of the bank layer 161 and the residual pattern 153 in the third direction (Z-axis direction). Other redundant description will be omitted.

The first encapsulation layer 171 of an embodiment may completely cover the first light emitting element ED1 at a portion overlapped with the first opening OP1, and may completely cover the pixel defining layer 151, the bank layer 161, the first organic pattern ELP1 and the first capping pattern CP1 at portions overlapped with the second opening OP2 and the non-light emission area NLA. The second encapsulation layer 173 of an embodiment may planarize the step difference formed by the first encapsulation layer 171 at a portion overlapped with the first opening OP1. Other redundant description will be omitted.

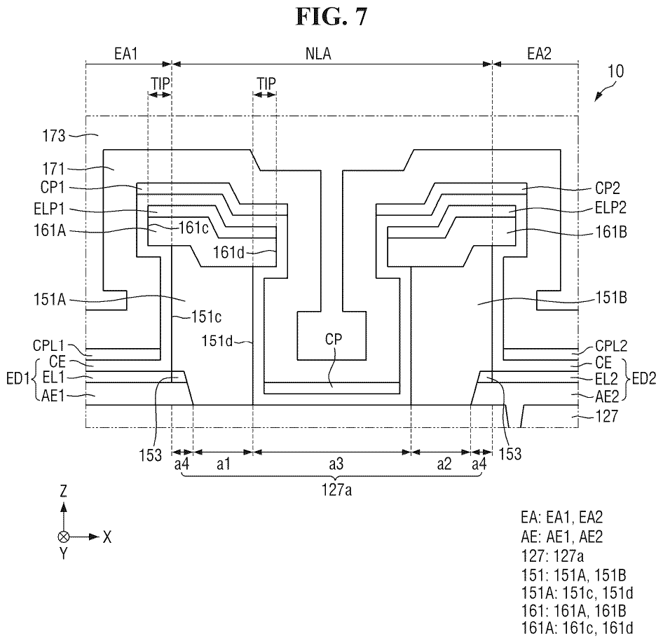

FIG. 7 is an enlarged schematic cross-sectional view illustrating a non-light emission area NLA disposed between the first light emission area EA1 and the second light emission area EA2 in FIG. 5.

Referring to FIG. 7, the anode electrode AE, the pixel defining layer 151 and the cathode electrode CE may be positioned on the second via layer 127 of an embodiment.

In some embodiments, the second via layer 127 of an embodiment may include a first surface 127a directed toward the pixel defining layer 151. At a portion overlapped with the non-light emission area NLA, the first surface 127a of the second via layer 127 may be divided into a first portion a1, a second portion a2, a third portion a3, and a fourth portion a4 depending on a contact structure.

In detail, the first portion a1 may be a portion with which the first pixel defining layer 151A is in contact, the second portion a2 may be a portion with which the second pixel defining layer 151B is in contact, the third portion a3 may be a portion with which the cathode electrode CE is in contact, and the fourth portion a4 may be a portion with which the anode electrode AE is in contact. The third portion a3 may be positioned between the first portion a1 and the second portion a2, and may overlap the protruded tip TIP of the bank layer 161 in the third direction (Z-axis direction). In addition, the fourth portion a4 may overlap the residual pattern 153 in the third direction (Z-axis direction).

The first pixel defining layer 151A and the second pixel defining layer 151B according to an embodiment may be spaced apart from each other in the first direction (X-axis direction) with the cathode electrode CE, the capping pattern CP, the first encapsulation layer 171 and the second encapsulation layer 173, which are interposed therebetween.

In some embodiments, the first pixel defining layer 151A may include a first side 151c directed toward the light emission area EA and a second side 151d facing the first side 151c. The first side 151c and the second side 151d may be completely covered by the cathode electrode CE, and may be entirely in contact with the cathode electrode CE. In an embodiment, the cathode electrode CE covering the first side 151c and the cathode electrode CE covering the second side 151d may be integrally formed.

The first bank layer 161A and the second bank layer 161B according to an embodiment may be spaced apart from each other in the first direction (X-axis direction) with the first encapsulation layer 171 and the second encapsulation layer 173, which are interposed therebetween.

In some embodiments, the first bank layer 161A may include a first side 161c directed toward the light emission area EA and a second side 161d facing the first side 161c. The first side 161c and the second side 161d may be completely covered by the cathode electrode CE, and may be entirely in contact with the cathode electrode CE. In an embodiment, the cathode electrode CE covering the first side 161c and the cathode electrode CE covering the second side 161d may be integrally formed.

The first side 161c of the bank layer 161 according to an embodiment may be more protruded toward the light emission area EA than the first side 151c of the pixel defining layer 151, and the second side 161d of the bank layer 161 may be more protruded toward one side in the first direction (X-axis direction) than the second side 151d of the pixel defining layer 151 at a portion overlapped with the non-light emission area NLA. Therefore, the bank layer 161 of an embodiment may have tips TIP protruded to both sides in the first direction (X-axis direction).

The first organic pattern ELP1 and the second organic pattern ELP2 according to an embodiment may be spaced apart from each other in the first direction (X-axis direction) with the first encapsulation layer 171 and the second encapsulation layer 173, which are interposed therebetween. The first organic pattern ELP1 of an embodiment may be in contact with tips TIP protruded to both sides of the first bank layer 161A, and the second organic pattern ELP2 may be in contact with tips TIP protruded to both sides of the second bank layer 161B.

The first capping pattern CP1 and the second capping pattern CP2 according to an embodiment may be spaced apart from each other in the first direction (X-axis direction) with the first encapsulation layer 171 and the second encapsulation layer 173, which are interposed therebetween. The first capping pattern CP1 of an embodiment may overlap the tips TIP protruded to both sides of the first bank layer 161A, and the second capping pattern CP2 may overlap the tips TIP protruded to both sides of the second bank layer 161B.

The capping pattern CP disposed between the first pixel defining layer 151A and the second pixel defining layer 151B may be formed in such a manner that a material for forming the capping layer CPL is not only deposited on a portion overlapped with the bank layer 161 but also deposited on an overlap portion between the first pixel defining layer 151A and the second pixel defining layer 151B as the bank layer 161 includes the tip TIP at a portion overlapped with the non-light emission area NLA during the fabricating process of the display device 10. The capping pattern CP disposed between the first pixel defining layer 151A and the second pixel defining layer 151B may be positioned in contact with the cathode electrode CE.

The first encapsulation layer 171 may completely cover the first capping pattern CP1 and the second capping pattern CP2 at a portion overlapped with the non-light emission area NLA, and may be in contact with the first capping pattern CP1 and the second capping pattern CP2. In addition, the first encapsulation layer 171 may completely cover the capping pattern CP deposited at the overlap portion between the first pixel defining layer 151A and the second pixel defining layer 151B at the portion overlapped with the non-light emission area NLA.

The second encapsulation layer 173 of an embodiment may planarize a step difference formed by the first encapsulation layer 171 at a portion overlapped with the non-light emission area NLA. Other redundant description will be omitted.

For convenience of description, the structure overlapped with the first light emission area EA1 and the structure overlapped with the non-light emission area NLA positioned between the first light emission area EA1 and the second light emission area EA2 have been shown and described, but a structure overlapped with the second light emission area EA2 and the third light emission area EA3 and its features may be the same as the structure overlapped with the first light emission area EA1 and its features.

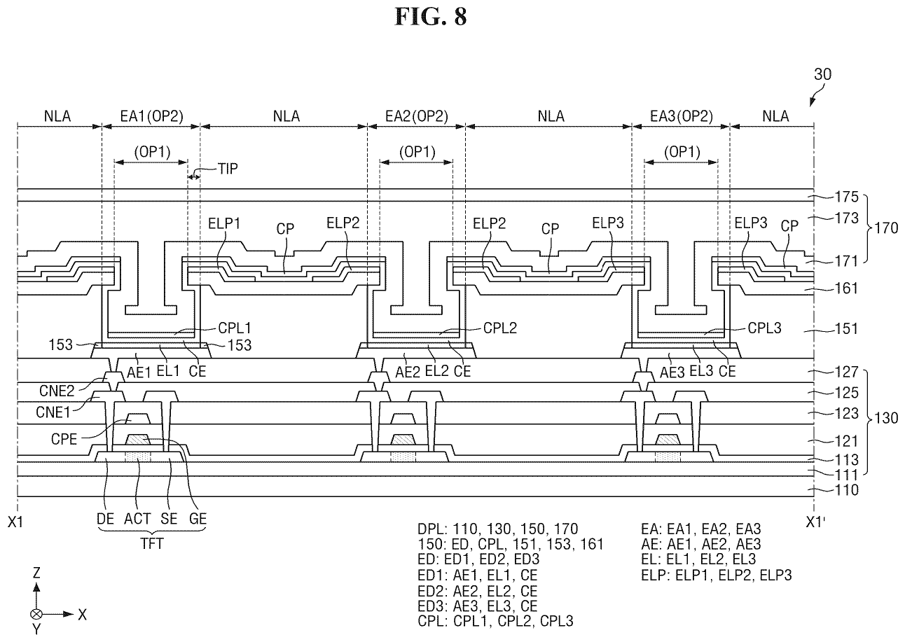

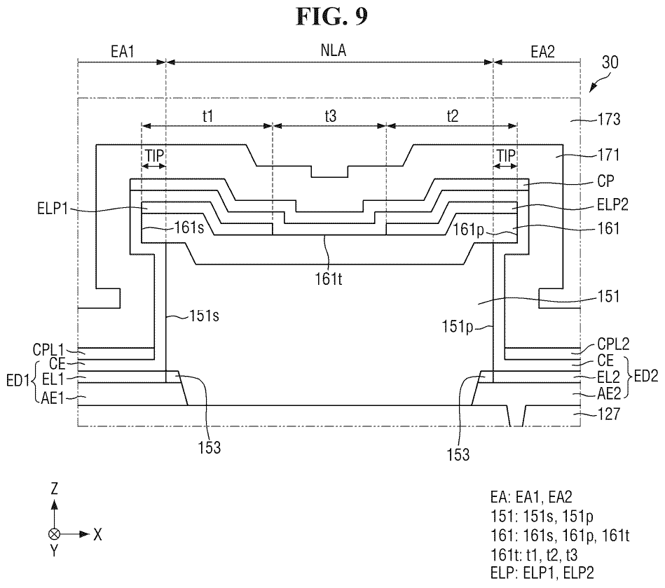

FIG. 8 is a schematic cross-sectional view illustrating a display device 30 taken along line X1-X1′ of FIG. 4 as another embodiment, and FIG. 9 is an enlarged schematic cross-sectional view illustrating a non-light emission area NLA disposed between a first light emission area EA1 and a second light emission area EA2 in FIG. 8.

Referring to FIGS. 8 and 9, a display device 30 of an embodiment may be different from the above-described display device 10 at least with respect to a structure of a portion overlapped with the non-light emission area NLA. Hereinafter, a redundant description of the display device 10 in the structure overlapped with the light emission area EA will be omitted, and differences from the display device 10 will be described.

The pixel defining layer 151 of an embodiment may be positioned on the second via layer 127 and the anode electrode AE at a portion overlapped with the non-light emission area NLA. Only the anode electrodes AE and the pixel defining layer 151 may be positioned on the second via layer 127 of an embodiment. The first to third anode electrodes AE1, AE2 and AE3 of an embodiment may be spaced apart and insulated from one another by the pixel defining layer 151.

In some embodiments, the pixel defining layer 151 of an embodiment may include a first side 151s and a second side 151p. The first side 151s may be a side directed toward the first light emission area EA1, and the second side 151p may be a side directed toward the second light emission area EA2. The first side 151s and the second side 151p may face each other.

The first and second sides 151s and 151p of an embodiment may be completely covered by the cathode electrode CE, and may be in contact with the cathode electrode CE. The cathode electrode CE that is in contact with the first side 151s and the cathode electrode CE that is in contact with the second side 151p may be integrally formed.

In the display device 30 of an embodiment, the first side 151s and the second side 151p of the pixel defining layer 151 may be formed to be entirely in contact with the cathode electrode CE, so that a contact force between the pixel defining layer 151 and the cathode electrode CE may be improved. Therefore, the display device 30 of an embodiment may resolve a detachable defect of the pixel defining layer 151 and the cathode electrode CE and a moisture permeation defect of the display device, which is caused by the detachable defect.

The bank layer 161 of an embodiment may be positioned on the pixel defining layer 151 at a portion overlapped with the non-light emission area NLA.

In some embodiments, the bank layer 161 of an embodiment may include a first side 161s and a second side 161p. The first side 161s may be a side directed toward the first light emission area EA1, and the second side 161p may be a side directed toward the second light emission area EA2. The first side 161s and the second side 161p may face each other.

The first side 161s of an embodiment may be more protruded toward the first light emission area EA1 than the first side 151s of the pixel defining layer 151, and thus the bank layer 161 may have a tip TIP protruded toward the first light emission area EA1. In addition, the second side 161p of an embodiment may be more protruded toward the second light emission area EA2 than the second side 151p of the pixel defining layer 151, and thus the bank layer 161 may have a tip TIP protruded toward the second light emission area EA2. That is, the bank layer 161 of an embodiment may have a tip TIP protruded to both sides toward the light emission area EA.

The first and second sides 161s and 161p of an embodiment may be completely covered by the cathode electrode CE, and may be in contact with the cathode electrode CE. The cathode electrode CE that is in contact with the first side 161s and the cathode electrode CE that is in contact with the second side 161p may be integrally formed.

In some embodiments, the bank layer 161 of an embodiment may further include a first surface 161t. The first surface 161t of the bank layer 161 may be a surface directed toward the capping pattern CP.

The first surface 161t of an embodiment may be divided into a first portion t1, a second portion t2, and a third portion t3 depending on a contact structure. The first portion t1 of an embodiment may be in contact with the first organic pattern ELP1, the second portion t2 may be in contact with the second organic pattern ELP2, and the third portion t3 may be in contact with the cathode electrode CE. The first portion t1 and the second portion t2 according to an embodiment may be spaced apart from each other with the third portion t3 interposed therebetween. In other words, the first organic pattern ELP1 and the second organic pattern ELP2 according to an embodiment may be spaced apart from each other on the bank layer 161 with the cathode electrode CE interposed therebetween.

The cathode electrode CE of an embodiment may be positioned on the organic pattern ELP and the bank layer 161 at a portion overlapped with the non-light emission area NLA, and may be in contact with the organic pattern ELP and the bank layer 161.

The capping pattern CP of an embodiment may completely cover the cathode electrode CE at a portion overlapped with the non-light emission area NLA, and may be in contact with the cathode electrode CE. The capping layer CPL of an embodiment may be formed in such a manner that a material for forming the capping layer CPL is not only formed on the anode electrode AE but also formed on the bank layer 161 during the fabricating process of the display device 30. Therefore, the capping pattern CP may be a result of the material for forming the capping layer CPL, which is disconnected by being connected with the first to third capping layers CPL1, CPL2 and CPL3 disposed in the light emission area EA, as the bank layer 161 includes the protruded tip TIP.

The first encapsulation layer 171 of an embodiment may completely cover the capping pattern CP at a portion overlapped with the non-light emission area NLA, and may be in contact with the capping pattern CP. The second encapsulation layer 173 of an embodiment may completely cover the first encapsulation layer 171 at a portion overlapped with the non-light emission area NLA. The second encapsulation layer 173 of an embodiment may planarize a step difference formed by the first encapsulation layer 171 at a portion overlapped with the non-light emission area NLA. Other redundant description will be omitted.

For convenience of description, the structure overlapped with the first light emission area EA1 and the second light emission area EA2 has been shown and described, but the third light emission area EA3 may have the same structure and features as those of the first light emission area EA1 and the second light emission area EA2.

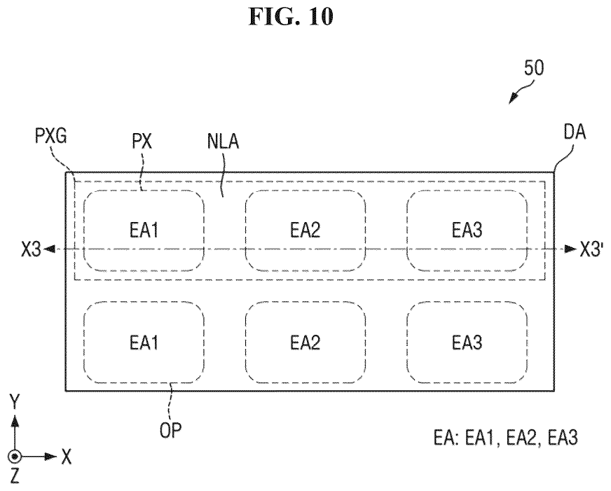

FIG. 10 is a schematic plan view illustrating arrangement of a light emission area in a display area DA of FIG. 3 as another embodiment.

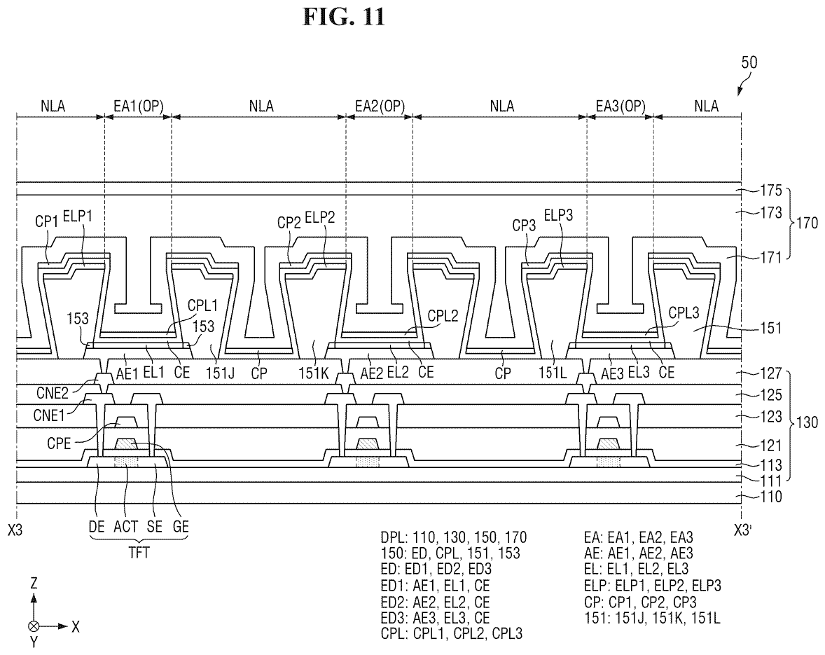

Referring to FIG. 10, a display device 50 according to an embodiment may be different from the above-described display device 10 at least in that the first to third light emission areas EA1, EA2 and EA3 may be defined through one opening OP. The pixel defining layer (151′ of FIG. 11), which will be described later, may be positioned in the non-light emission area NLA of an embodiment. Other redundant description will be omitted.

FIG. 11 is a schematic cross-sectional view illustrating a display device 50 taken along line X3-X3′ of FIG. 10. The display device 50 according to an embodiment may be different from the above-described display devices 10 and 30 at least in that the pixel defining layer 151 may have a reverse tapered shape and the organic pattern ELP may be directly disposed on the pixel defining layer 151. Hereinafter, a redundant description of the display device 10 and the display device 30 will be omitted, and differences therefrom will be described.

Referring to FIG. 11, the display device 50 according to an embodiment may include a pixel defining layer 151 at a portion overlapped with the non-light emission area NLA, and the pixel defining layer 151 may define the opening OP. The first to third light emission areas EA1, EA2 and EA3 of an embodiment may be defined through the opening OP.

The pixel defining layer 151 of an embodiment may be positioned on the second via layer 127 and the anode electrode AE. The pixel defining layer 151 of an embodiment may have a reverse tapered shape. That is, a width of a lower surface of the pixel defining layer 151, which is directed toward the second via layer 127, may be smaller than a width of an upper surface thereof, which is directed toward the organic pattern ELP.

In the display device 50 according to an embodiment, as the pixel defining layer 151 includes a reverse tapered shape, the first to third light emitting elements ED1, ED2 and ED3, which are spaced apart from one another, may be formed at portions overlapped with the first to third light emission areas EA1, EA2 and EA3 without a separate fine metal mask.

The pixel defining layer 151 of an embodiment may include both sides directed toward the light emission area EA and the non-light emission area NLA. Both sides of the pixel defining layer 151 according to an embodiment may be completely covered by the cathode electrode CE, and may be in contact with the cathode electrode CE.

In the display device 50 of an embodiment, both sides of the pixel defining layer 151 may be formed to be entirely in contact with the cathode electrode CE, so that a contact force between the pixel defining layer 151 and the cathode electrode CE may be improved. Therefore, the display device 50 of an embodiment may resolve a detachable defect of the pixel defining layer 151 and the cathode electrode CE and a moisture permeation defect of the display device 50, which is caused by the detachable defect.

In some embodiments, the pixel defining layer 151 may include a first pixel defining layer 151J, a second pixel defining layer 151K, and a third pixel defining layer 151L. In an embodiment, the first pixel defining layer 151J may be disposed toward the first light emission area EA1, the second pixel defining layer 151K may be disposed toward the second light emission area EA2, and the third pixel defining layer 151L may be positioned toward the third light emission area EA3. At a portion overlapped with the non-light emission area NLA, the first pixel defining layer 151J and the second pixel defining layer 151K may be spaced apart from each other in the first direction (X-axis direction), and the second pixel defining layer 151K and the third pixel defining layer 151L may be spaced apart from each other in the first direction (X-axis direction). The first pixel defining layer 151J, the second pixel defining layer 151K and the third pixel defining layer 151L may be integrally formed during the fabricating process of the display device 10, and then may be formed to be spaced apart from one another by a subsequent etching process.

The organic pattern ELP of an embodiment may be positioned in contact with the pixel defining layer 151. The organic pattern ELP of an embodiment may be positioned while surrounding the opening OP. The organic pattern ELP of an embodiment may include a first organic pattern ELP1, a second organic pattern ELP2, and a third organic pattern ELP3. The first organic pattern ELP1 may be positioned on the first pixel defining layer 151J, the second organic pattern ELP2 may be positioned on the second pixel defining layer 151K, and the third organic pattern ELP3 may be positioned on the third pixel defining layer 151L.

In the fabricating process of the display device 50, the light emitting layer EL of an embodiment may be formed by deposition and photo patterning processes without using a separate fine metal mask. Therefore, the material for forming the light emitting layer EL in the fabricating process of the display device 50 may be not only deposited on the anode electrode AE but also deposited on the pixel defining layer 151. That is, the organic pattern ELP of an embodiment may be a mark of the material of the light emitting layer EL deposited on the pixel defining layer 151, which is formed by being disconnected from the light emitting layer EL deposited on the anode electrode AE, as the pixel defining layer 151 includes the reverse tapered shape. In other words, it can be seen that the display device 50 of an embodiment includes the organic pattern ELP on the pixel defining layer 151, and thus the process of forming the light emitting layer EL is performed by the photo patterning process.

The capping pattern CP of an embodiment may be positioned at a portion overlapped with the pixel defining layer 151, and may be in contact with the cathode electrode CE. The capping pattern CP of an embodiment may be positioned at portions overlapped with the light emission area EA and the non-light emission area NLA.

The capping pattern CP of an embodiment may include a first capping pattern CP1, a second capping pattern CP2, and a third capping pattern CP3. The first capping pattern CP1 may be positioned on the first pixel defining layer 151J, the second capping pattern CP2 may be positioned on the second pixel defining layer 151K, and the third capping pattern CP3 may be positioned on the third pixel defining layer 151L.

The capping pattern CP of an embodiment may be a mark of the material of the capping layer CPL deposited on the pixel defining layer 151, which is formed by being disconnected from the capping layer CPL deposited on the anode electrode AE, as the pixel defining layer 151 has the reverse tapered shape. In other words, it can be seen that the display device 50 of an embodiment includes the capping pattern CP on the pixel defining layer 151, and thus the process of forming the capping layer CPL is performed by the photo patterning process. Other redundant description will be omitted.

In addition, the capping pattern CP of an embodiment may be deposited on the cathode electrode CE at an overlap portion between the first pixel defining layer 151J and the second pixel defining layer 151K and between the second pixel defining layer 151K and the third pixel defining layer 151L at the portion overlapped with the non-light emission area NLA. The first to third capping patterns CP1, CP2 and CP3 formed on the bank layer 161 and the capping pattern CP formed between the pixel defining layers 151 may be spaced apart from each other. Other redundant description will be omitted.

FIGS. 12 to 22 are schematic cross-sectional views illustrating a method of fabricating a display element layer 150 and a thin film encapsulation layer 170, which are included in the display device 10 of FIG. 5.

Referring to FIG. 12, anode electrodes AE, a sacrificial layer SFL, a pixel defining material layer 151L and a bank material layer 161L may be formed on a thin film transistor layer 130. Although not shown in the drawing, the thin film transistor layer 130 may be positioned on a substrate 110, and a structure of the thin film transistor layer 130 is the same as that described with reference to FIG. 5. A detailed description of such elements will be omitted.

The anode electrodes AE may be positioned to be spaced apart from each other on the thin film transistor layer 130. For example, the anode electrode AE may include first to third anode electrodes AE1, AE2 and AE3. The sacrificial layer SFL may be positioned on each of the first to third anode electrodes AE1, AE2 and AE3. The sacrificial layer SFL may assist so that an upper surface of the anode electrode AE and the pixel defining material layer 151L are not in contact with each other.

The sacrificial layer SFL may include an oxide semiconductor. For example, the sacrificial layer SFL may include at least one of indium gallium zinc oxide (IGZO), zinc tin oxide (ZTO), and indium tin oxide (IZO).

The pixel defining material layer 151L may be disposed to entirely cover the sacrificial layer SFL and the thin film transistor layer 130, and the bank material layer 161L may be positioned to entirely cover the pixel defining material layer 151L.

The pixel defining material layer 151L and the bank material layer 161L according to an embodiment may include their respective materials different from each other, and the bank material layer 161L may include a material that is more stable for an etching solution than the pixel defining material layer 151L. For example, in case that the pixel defining material layer 151L is silicon oxide, the bank material layer 161L may be titanium (Ti), and in case that the pixel defining material layer 151L is silicon oxynitride, the bank material layer 161L may be silicon oxide, but the disclosure is not limited thereto.

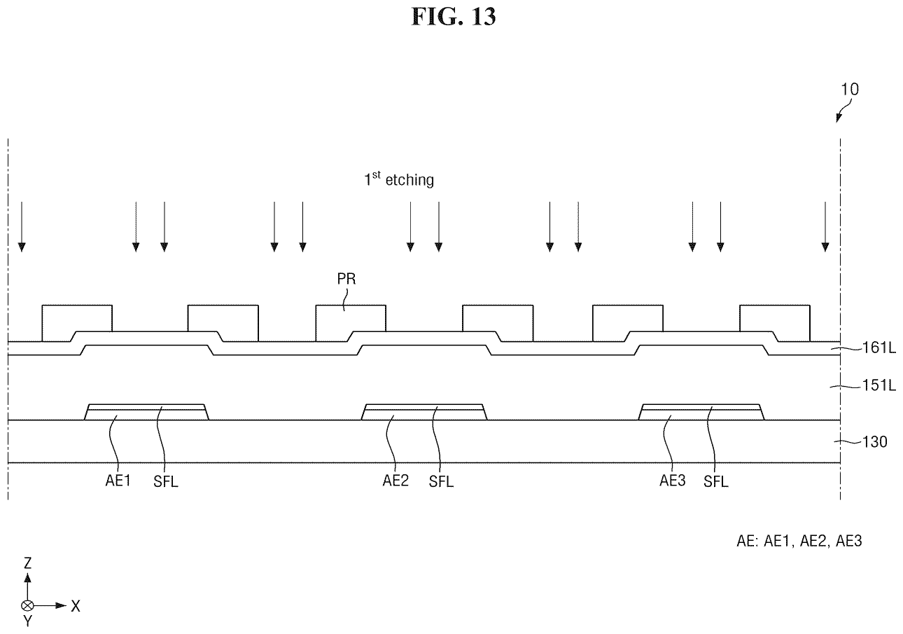

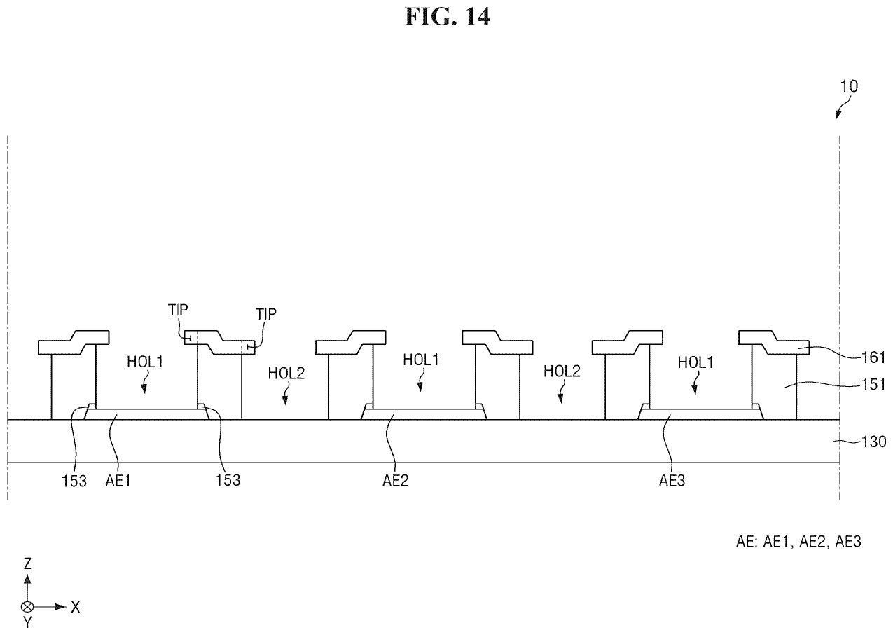

Referring to FIGS. 13 and 14, photoresists PRs may be formed on the bank material layer 161L, and a first etching process may be performed using the photoresist PR as a mask. For example, the first etching process may be performed in such a manner that a dry etching process and a wet etching process are alternately performed.

In the process, the pixel defining material layer 151L, the bank material layer 161L and the sacrificial layer SFL, at which the photoresist PR is not formed, may be removed. Therefore, a first hole HOL1 may be formed at a portion overlapped with each of the first to third anode electrodes AE1, AE2 and AE3, and a second hole HOL2 may be formed at a portion that is not overlapped with the anode electrode AE.

In the process, a portion of the sacrificial layer SFL may be removed at a portion overlapped with the first hole HOL1, and thus the first to third anode electrodes AE1, AE2 and AE3 may be exposed at the portion overlapped with the first hole HOL1. A portion of the sacrificial layer SFL which is not removed in the process may remain as the residual pattern 153 shown in FIG. 5.

In the process, the pixel defining material layer 151L and the bank material layer 161L may be formed in the form of the pixel defining layer 151 and the bank layer 161, which are shown in FIG. 5. As described above, since the bank material layer 161L of an embodiment includes a material that is more stable for an etching process than the pixel defining material layer 151L, the bank layer 161 may have tips TIP more protruded to both sides than a side of the pixel defining layer 151.

Through the process, a portion of the thin film transistor layer 130 may be exposed again at a portion overlapped with the second hole HOL2, and the pixel defining layer 151 may be spaced apart from another one in the first direction (X-axis direction) with the first hole HOL1 and the second hole HOL2, which are interposed therebetween.

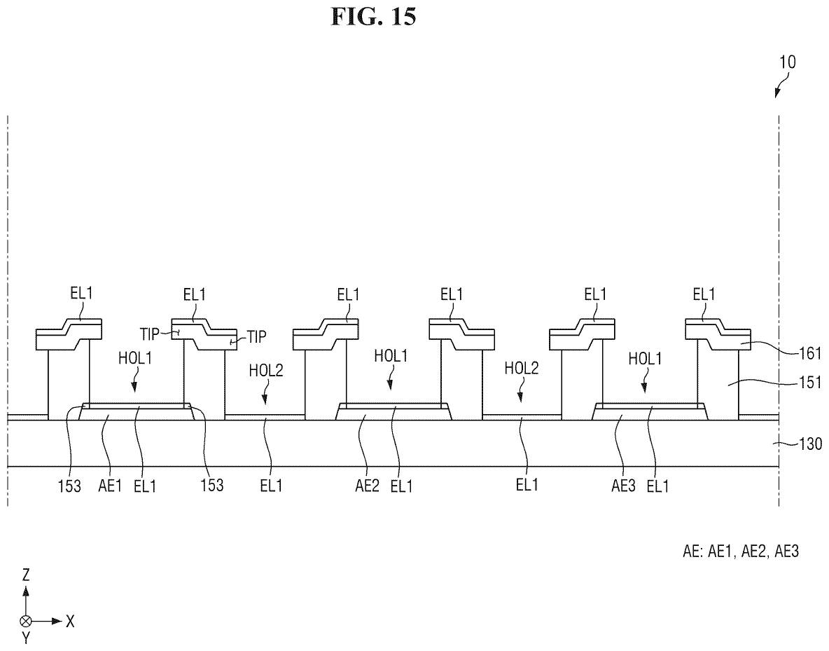

Referring to FIG. 15, a first light emitting layer EL1 may be formed on the first anode electrode AE1. In the display device 10 according to an embodiment, as the bank layer 161 includes a tip TIP protruded to both sides, a material for forming the first light emitting layer EL1 may be formed on the first anode electrode AE1 by deposition and photo patterning processes without a separate fine metal mask.

The first light emitting layer EL1 of an embodiment may be performed by a thermal deposition process. The first light emitting layer EL1 of an embodiment may be formed by the deposition process by being inclined at an angle of 45° to 50° from an upper surface of the first anode electrode AE1. Therefore, the first light emitting layer EL1 may also be formed on the first anode electrode AE1 positioned under the tip TIP of the bank layer 161. The first light emitting layer EL1 may also be in contact with the residual pattern 153 formed on the first anode electrode AE1.

In the process, the first light emitting layer EL1 may be deposited on the second anode electrode AE2 and the third anode electrode AE3 at a portion overlapped with the first hole HOL1, may be deposited on the thin film transistor layer 130 at a portion overlapped with the second hole HOL2, and may also be deposited on the bank layer 161.

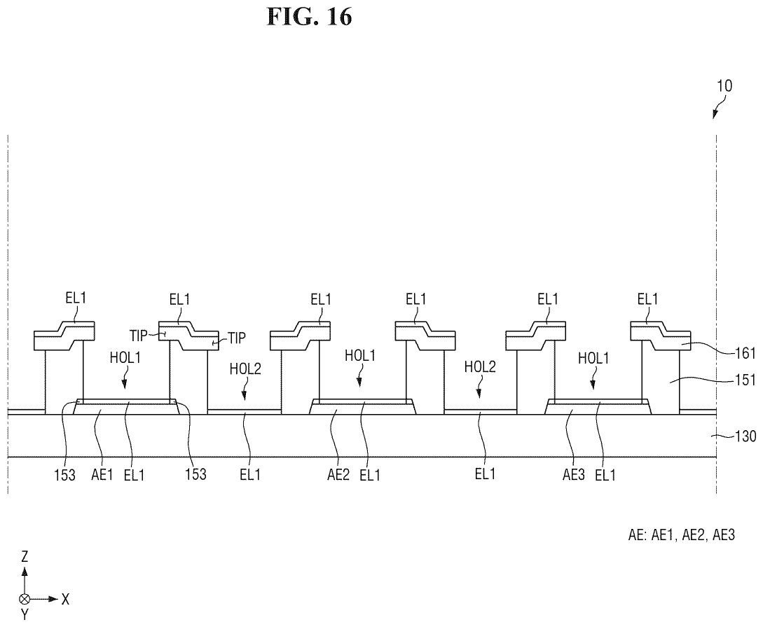

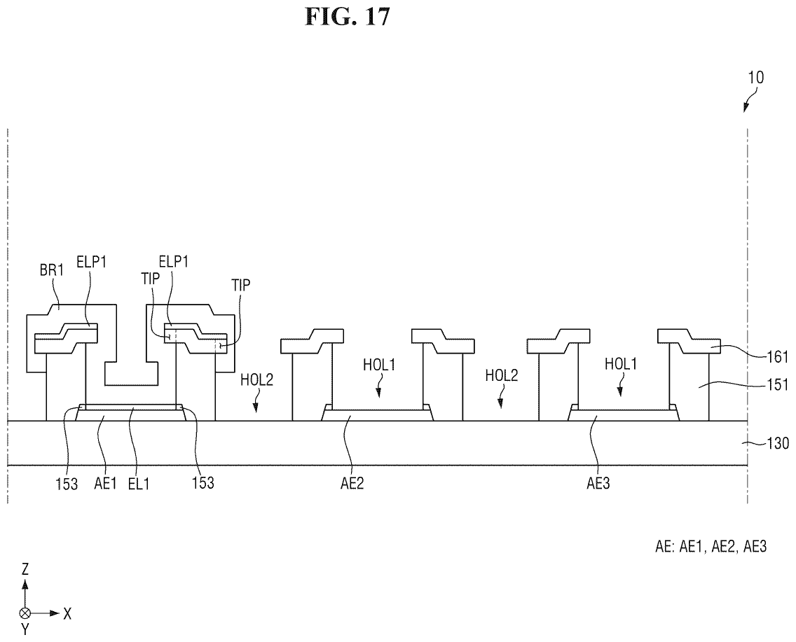

Referring to FIGS. 16 and 17, a first temporary barrier layer BR1 may be entirely formed on the first light emitting layer EL1. The first temporary barrier layer BR1 may protect the first light emitting layer EL1, the pixel defining layer 151 and the bank layer 161 at a portion overlapped with the first anode electrode AE1 in a subsequent etching process. The first temporary barrier layer BR1 may be an inorganic insulating material, for example, silicon nitride.

The photoresist PR may be formed on a portion overlapped with the first anode electrode AE1 and the periphery of the first anode electrode AE1, and a second etching process may be performed using the photoresist PR as a mask. For example, the second etching process may be a dry etching process.

In the process, the first temporary barrier layer BR1 and the first light emitting layer EL1, which are overlapped with the first anode electrode AE1 and the periphery of the first anode electrode AE1, may remain, and the first light emitting layer EL1 formed on the bank layer 161 positioned near the first anode electrode AE1 may be formed in the form of the first organic pattern ELP1 shown in FIG. 5.

In addition, the first temporary barrier layer BR1 and the first light emitting layer EL1, which are overlapped with the second anode electrode AE2 and the third anode electrode AE3, may be removed. As a result, the second anode electrode AE2 and the third anode electrode AE3 may be exposed, and the first hole HOL1 may be formed at portions overlapped with the second anode electrode AE2 and the third anode electrode AE3. In addition, the second hole HOL2 may be formed at a portion that is not overlapped with the anode electrode AE, and the thin film transistor layer 130 at a portion overlapped with the second hole HOL2 may be exposed.

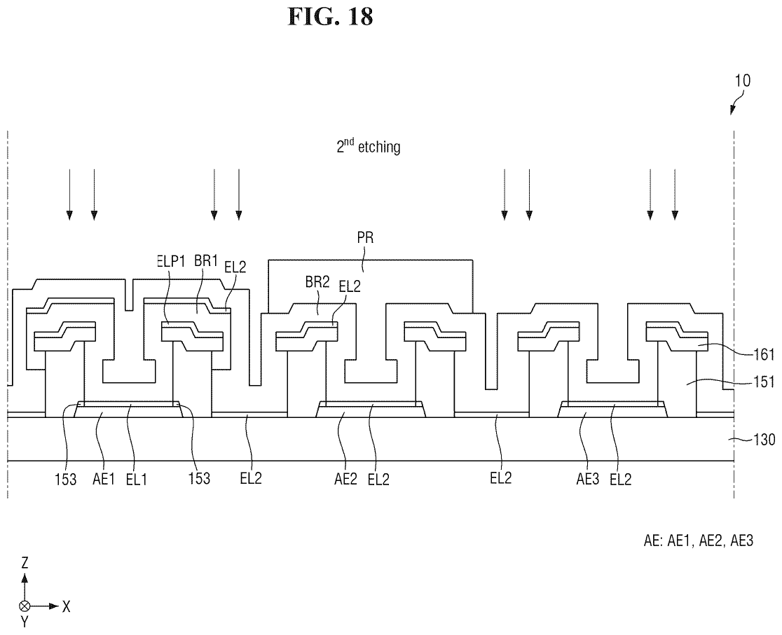

Referring to FIG. 18, the above-described process may be repeated so that a second light emitting layer EL2 is formed on the second anode electrode AE2. In detail, the second light emitting layer EL2 may be not only deposited on the second anode electrode AE2 but also deposited on the first temporary barrier layer BR1 at a portion overlapped with the first anode electrode AE1, and may also be deposited on the third anode electrode AE3 at a portion overlapped with the third anode electrode AE3. In addition, the second light emitting layer EL2 may also be deposited at a portion that is not overlapped with the bank layer 161 and the anode electrodes AE.

A second temporary barrier layer BR2 may be entirely formed on the second light emitting layer EL2. The second temporary barrier layer BR2 may protect the second light emitting layer EL2, the pixel defining layer 151 and the bank layer 161 at a portion overlapped with the second anode electrode AE2 in a subsequent etching process. The second temporary barrier layer BR2 may be not only deposited on the second anode electrode AE2 but also deposited on the first temporary barrier layer BR1 and the third anode electrode AE3. The second temporary barrier layer BR2 may be an inorganic insulating material, for example, silicon nitride.

The photoresist PR may be formed at a portion overlapped with the second anode electrode AE2 and the periphery of the second anode electrode AE2, and the second etching process may be performed again using the pore resist PR as a mask. A redundant description will be omitted.

After a third light emitting layer EL3 is formed on the third anode electrode AE3 by repeating the above-described process, a third temporary barrier layer BR3 may be formed, the photoresist PR may be formed at a portion overlapped with the third anode electrode AE3 and the periphery of the third anode electrode AE3, and the second etching process may be performed again. A redundant description will be omitted.

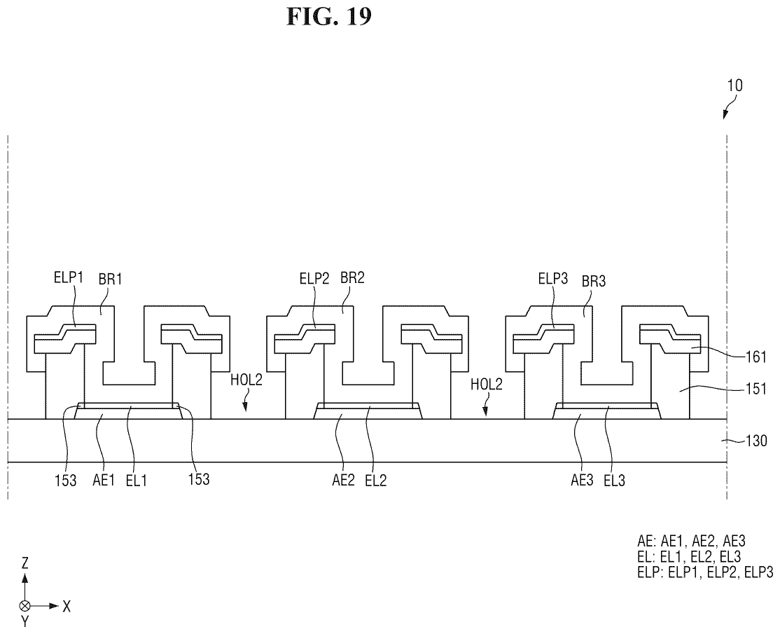

As shown in FIG. 19 through the above-described process, the second temporary barrier layer BR2 and the second light emitting layer EL2, which are overlapped with the second anode electrode AE2 and the periphery of the second anode electrode AE2, may remain, and the second light emitting layer EL2 formed on the bank layer 161 positioned near the second anode electrode AE2 may be formed in the form of the second organic pattern ELP2 shown in FIG. 5.

The third temporary barrier layer BR3 and the third light emitting layer EL3, which are overlapped with the third anode electrode AE3 and the periphery of the third anode electrode AE3, may remain, and the third light emitting layer EL3 formed on the bank layer 161 positioned near the third anode electrode AE3 may be formed in the form of the third organic pattern ELP3 shown in FIG. 5.

In the process, the second hole HOL2 may be formed at a portion that is not overlapped with the anode electrode AE, and a portion of the thin film transistor layer 130 may be exposed at a portion overlapped with the second hole HOL2.

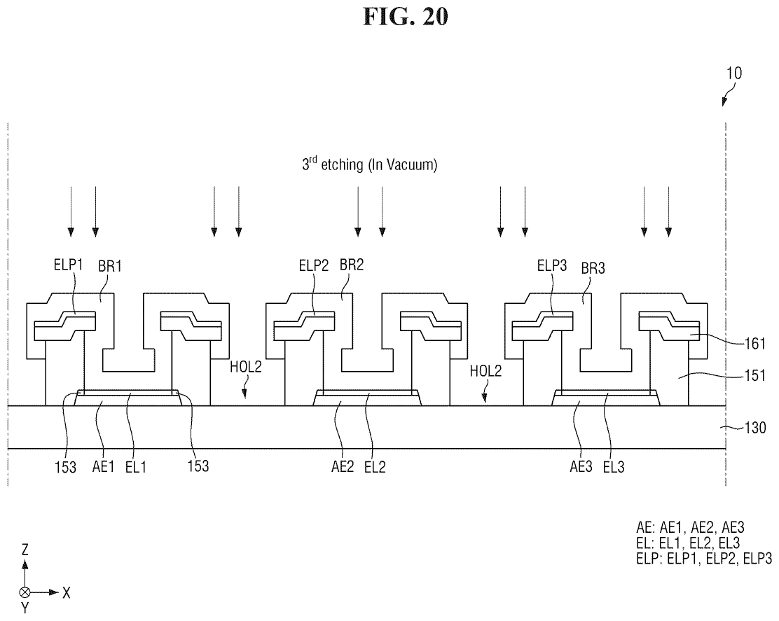

Referring to FIG. 20, the display device 10 may be introduced into a vacuum chamber so that a third etching process may be performed. For example, the third etching process may be performed by a dry etching process. In the process, the first to third temporary barrier layers BR1, BR2 and BR3 may be removed, and thus the light emitting layers EL and the organic patterns ELP may be exposed.

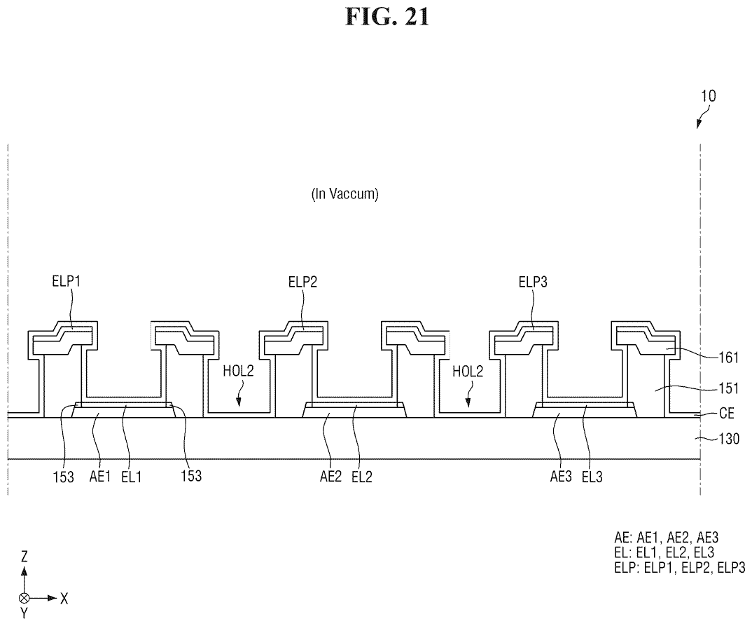

Referring to FIG. 21, a cathode electrode CE may be entirely deposited at portions overlapped with the anode electrodes AE, the organic patterns ELP and the second hole HOL2 while maintaining a vacuum state. The cathode electrode CE of an embodiment may be a common electrode that is entirely deposited. As a result, the cathode electrode CE may completely cover the thin film transistor layer 130 overlapped with the anode electrodes AE, the organic patterns ELP and the second hole HOL2.

The cathode electrode CE of an embodiment may be performed by a sputtering or thermal deposition method. The process of forming the cathode electrode CE of an embodiment may have a higher step coverage than the process of forming the light emitting layer EL. Therefore, the display device 10 according to an embodiment may completely cover the light emitting layer EL, the pixel defining layer 151, the bank layer 161 and the organic pattern ELP in the process of forming the cathode electrode CE.

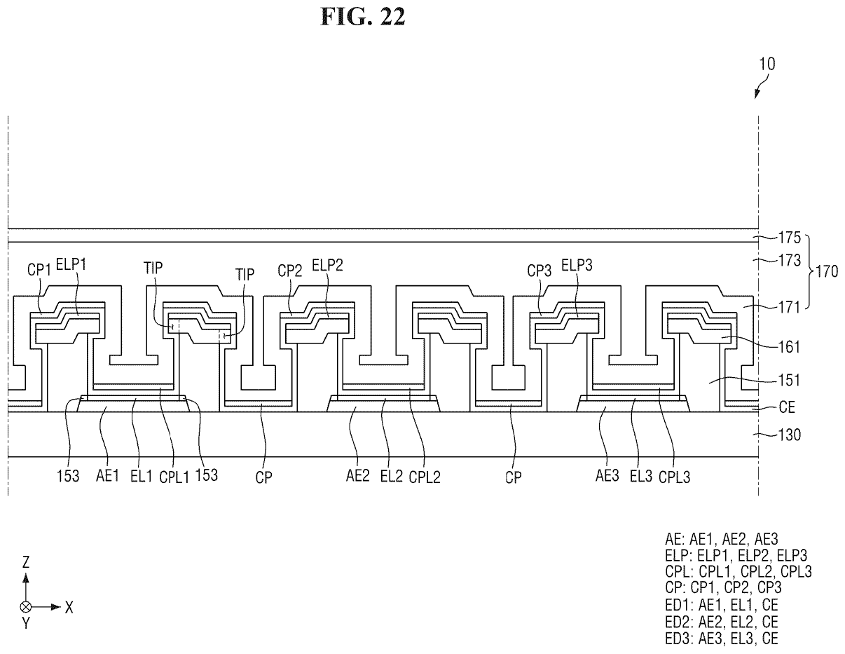

Referring to FIG. 22, a capping layer CPL may be entirely formed on the cathode electrode CE. In the display device 10 according to an embodiment, as the bank layer 161 includes tips protruded to both sides, the capping layer CPL may be formed to be spaced apart from portions overlapped with the first to third anode electrodes AE1, AE2 and AE3 even without a separate fine metal mask. Through the process, a material for forming the capping layer CPL formed on the first to third anode electrodes AE1, AE2 and AE3 may be formed of that of the first to third capping layers CPL1, CPL2 and CPL3 shown in FIG. 5.

In addition, the material for forming the capping layer CPL may also be formed on the bank layer 161 or on the thin film transistor layer 130 at a portion that is not overlapped with the anode electrode AE. Through the process, the material of the capping layer CPL formed on the bank layer 161 may be formed in the form of the first to third capping patterns CP1, CP2 and CP3 shown in FIG. 5, and the material of the capping layer CPL formed at a portion that is not overlapped with the anode electrode AE may be formed in the form of the capping pattern CP shown in FIG. 5.

The first encapsulation layer 171 completely covering the capping layer CPL and the capping pattern CP may be formed. The first encapsulation layer 171 may be performed by a chemical vapor deposition (CVD) process, and may form a uniform film regardless of a step difference of a lower structure.

A second encapsulation layer 173 may be formed to planarize the step included in the first encapsulation layer 171, and a third encapsulation layer 175 may be formed. As a result, the display element layer 150 and the thin film encapsulation layer 170, which are shown in FIG. 5, may be formed.

A display device 10 according to an embodiment may include the pixel defining layer 151 and the bank layer 161, thereby forming a light emitting device ED that overlaps and is spaced apart from each of the first to third anode electrodes AE1, AE2 and AE3. The display device 10 according to an embodiment may include a cathode electrode CE that entirely covers both sides of the pixel defining layer 151, thereby improving a contact force between the pixel defining layer 151 and the cathode electrode CE. In addition, the display device 10 according to an embodiment may have high contact characteristics between the pixel defining layer 151 and the cathode electrode CE, and may include the first encapsulation layer 171 entirely covering the lower structure, thereby resolving a moisture permeation defect of the display device 10.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a substrate including a light emission area and a non-light emission area;
an anode electrode on the light emission area of the substrate;
a light emitting layer on the anode electrode;
a first pixel defining layer on the non-light emission area of the substrate, including a first side directed toward the light emission area;
a bank layer on the first pixel defining layer, including a tip more protruded toward the light emission area than the first side of the first pixel defining layer;
a residual pattern that overlaps the non-light emission area and is disposed between the anode electrode and the first pixel defining layer in a direction perpendicular to the substrate;
a cathode electrode on the light emitting layer and the bank layer; and
an encapsulation layer on the cathode electrode, wherein
the first pixel defining layer and the bank layer are completely overlapped by the cathode electrode, and
the entire first side of the first pixel defining layer physically contacts the cathode electrode.

2. The display device of claim 1, wherein
the first pixel defining layer further includes a second side facing the first side, and
the entire second side entirely physically contacts the cathode electrode.

3. The display device of claim 2, wherein the cathode electrode that physically contacts the first side and the cathode electrode that physically contacts the second side are integral to each other.

4. The display device of claim 2, wherein the bank layer further includes a tip more protruded than the second side.

5. The display device of claim 4, wherein
the tip of the bank layer is more protruded than the first side,
the tip of the bank layer, which is more protruded than the first side, overlaps the light emission area, and
the tip of the bank layer, which is more protruded than the second side, overlaps the non-light emission area.

6. The display device of claim 4, wherein
the tip of the bank layer is more protruded than the first side, and
the tip of the bank layer, which is more protruded than the first side and the second side, overlaps the light emission area.

7. The display device of claim 1, wherein a height of the first pixel defining layer is greater than a height of the bank layer in a direction perpendicular to the substrate.

8. The display device of claim 7, wherein the first pixel defining layer and the bank layer include different materials.

9. The display device of claim 8, wherein
the first pixel defining layer includes at least one of silicon oxide and silicon oxynitride, and
the bank layer includes at least one of titanium, silicon oxide, and silicon oxynitride.

10. The display device of claim 1, further comprising:
an organic pattern between the bank layer and the cathode electrode in a direction perpendicular to the substrate, wherein
the organic pattern and the light emitting layer include a same material,
the organic pattern is spaced apart from the light emitting layer, and
the cathode electrode overlaps the light emitting layer and the organic pattern.

11. The display device of claim 1, wherein
the bank layer defines a first opening,
the first pixel defining layer defines a second opening, and
the first opening is disposed inside the second opening.

12. The display device of claim 11, wherein the first opening is completely surrounded by the second opening in a plan view.

13. The display device of claim 1, further comprising:
a second pixel defining layer spaced apart from the first pixel defining layer in a direction parallel with the substrate by overlapping the non-light emission area.

14. The display device of claim 13, wherein
the substrate includes a surface directed toward the anode electrode, and
by overlapping the non-light emission area, the surface includes:
a first portion physically contacting the first pixel defining layer;
a second portion physically contacting the second pixel defining layer; and
a third portion physically contacting the cathode electrode.

15. The display device of claim 14, wherein
the first portion and the second portion are spaced apart from each other, and
the third portion is disposed between the first portion and the second portion.

16. The display device of claim 14, further comprising:
a capping layer disposed on the cathode electrode at a portion overlapping the light emission area; and
a capping pattern on the bank layer, wherein
the capping pattern and the capping layer include a same material, and
the capping layer and the capping pattern are spaced apart from each other.

17. A display device, comprising:
a substrate including a light emission area and a non-light emission area;
an anode electrode on the light emission area of the substrate;
a light emitting layer on the anode electrode;
a pixel defining layer on the non-light emission area of the substrate, having a reverse tapered shape;
an organic pattern on the pixel defining layer, and spaced apart from the light emitting layer;
a residual pattern that overlaps the non-light emission area and is disposed between the anode electrode and the pixel defining layer in a direction perpendicular to the substrate; and
a cathode electrode on the light emitting layer and the organic pattern, wherein
the organic pattern and the light emitting layer include a same material,
the cathode electrode completely overlaps the pixel defining layer and the organic pattern, and
both sides of the pixel defining layer entirely physically contact the cathode electrode.

18. The display device of claim 17, further comprising:
a second pixel defining layer spaced apart from the pixel defining layer in a direction parallel with the substrate by overlapping the non-light emission area,
wherein the second pixel defining layer has a reverse tapered shape.

19. The display device of claim 18, wherein the pixel defining layer and the second pixel defining layer physically contact the residual pattern.

20. A method of fabricating a display device, the method comprising:
forming a substrate including a light emission area and a non-light emission area, forming an anode electrode on the light emission area of the substrate, forming a sacrificial layer on the anode electrode, forming a pixel defining material layer entirely overlapping the substrate and the sacrificial layer, and forming a bank layer entirely overlapping the pixel defining layer;
forming photoresists on the bank layer and forming a first hole overlapped with the anode electrode and a second hole that is not overlapped with the anode electrode by performing a first etching process using the photoresists as masks, so that the anode electrode is exposed by overlapping the first hole, the sacrificial layer is formed as a residual pattern, and the bank layer forms a tip more protruded toward both sides than both sides of the pixel defining layer; and
entirely forming a light emitting layer and a temporary barrier layer on the anode electrode and the bank layer and forming a photoresist on a portion overlapped with the anode electrode and a periphery of the anode electrode, and removing the light emitting layer and the temporary barrier layer at a portion where the photoresist is not formed, by performing a second etching process; and
removing the temporary barrier layer disposed on the light emitting layer inside a vacuum chamber through a dry etching process, and entirely forming a cathode electrode and an encapsulation layer,
wherein both sides of the pixel defining layer entirely physically contact the cathode electrode.
